(19) United States
(12) Patent Application Publication
(10) Pub. No.: US 2021/0175438 A1
(43) Pub. Date: Jun. 10, 2021

(54) LAMINATE, LIQUID CRYSTAL DISPLAY DEVICE, AND ORGANIC ELECTROLUMINESCENT DEVICE

(71) Applicant: FUJIFILM Corporation, Tokyo (JP)

(72) Inventors: Masato MORITA, Kanagawa (JP); Naoya SHIBATA, Kanagawa (JP)

(73) Assignee: FUJIFILM Corporation, Tokyo (JP)

(21) Appl. No.: 17/160,927

(22) Filed: Jan. 28, 2021

Related U.S. Application Data
(63) Continuation of application No. PCT/JP2019/029773, filed on Jul. 30, 2019.

(30) Foreign Application Priority Data
Aug. 6, 2018 (JP) 2018-148032

(51) Int. Cl. H01L 51/00; G02F 1/1335; H01L 51/52; H01L 27/32; B32B 17/10; B32B 7/023; B32B 27/30

(52) U.S. Cl. CPC H01L 51/0076; G02F 1/1335; H01L 51/5293; H01L 27/32; B32B 17/10; B32B 7/023; B32B 2457/206; B32B 2250/05; B32B 2305/55; B32B 2307/42; B32B 2307/422; B32B 2315/08; B32B 2329/04; B32B 27/306

(57) ABSTRACT

A laminate which has a phase difference layer and has excellent thermal durability; a liquid crystal display device; and an organic electroluminescent device. The laminate is a laminate having two substrates, and a polarizing plate disposed between the two substrates, in which the polarizing plate has a polarizer and a phase difference layer, the phase difference layer is a layer formed of a composition containing a reciprocal wavelength dispersible liquid crystal compound, one of the two substrates is a glass substrate having a Na₂O content of 5% by mass or less, and the other of the two substrates is a glass substrate having a Na₂O content of 5% by mass or less, an inorganic compound film having a moisture permeability of 10⁻³ g/m²·day or less and a thickness of less than 1 μm, or an organic-inorganic hybrid film having a moisture permeability of 10⁻³ g/m²·day or less.

### CROSS-REFERENCE TO RELATED APPLICATIONS

This application is a Continuation of PCT International Application No. PCT/JP2019/029773 filed on Jul. 30, 2019, which was published under PCT Article 21(2) in Japanese, and which claims priority under 35 U.S.C. § 119(a) to Japanese Patent Application No. 2018-148032 filed on Aug. 6, 2018. The above applications are hereby expressly incorporated by reference, in their entirety, into the present application.

### BACKGROUND OF THE INVENTION

### 1. Field of the Invention

The present invention relates to a laminate, a liquid crystal display device, and an organic electroluminescent device.

### 2. Description of the Related Art

In the related art, a polarizing plate having a phase difference layer and a polarizer has been used for a liquid crystal display device, an organic electroluminescent device, or the like, for the purpose of optical compensation, antireflection, or the like.

In recent years, development of a polarizing plate (so-called broadband polarizing plate) which can provide the same effects to white light which is a composite wave having light rays in a visible light range coexisting therein, in correspondence to light rays at all wavelengths, has been in progress, and in particular, due to a demand for reduction in a thickness of a device to which a polarizing plate is applied, reduction in a thickness of a phase difference layer included in the polarizing plate has also been demanded.

In response to the above demands, for example, WO2014/010325A and JP2011-207765A each propose use of a liquid crystal compound exhibiting reciprocal wavelength dispersibility as a liquid crystal compound which is used for forming a phase difference layer.

### SUMMARY OF THE INVENTION

However, it has been found that in a case where a polarizing plate having a phase difference layer which is formed of the liquid crystal compound having reciprocal wavelength dispersibility described in WO2014/010325A and JP2011-207765A is manufactured, and the polarizing plate is interposed between glass and glass from both sides in accordance with a practical mode (for example, a circularly polarizing plate for the purpose of antireflection of an organic electroluminescence-type smartphone), and exposed for a long period of time under the condition of a high temperature, reddish unevenness occurs in an in-plane central part of the laminate. As a result of the analysis, it has been clarified that an in-plane retardation (Re) significantly varies in a reddish region, thereby causing a change in a tint. Therefore, development of a laminate which has a polarizer and a phase difference layer and in which a change in an in-plane retardation is suppressed even in a case of being exposed to a high temperature for a long period of time was desired. Hereinafter, suppressing a change in an in-plane retardation in a case where a laminate is exposed to a high temperature will be expressed as excellent thermal durability.

Accordingly, an object of the present invention is to provide a laminate which has a phase difference layer and has excellent thermal durability.

Moreover, another object of the present invention is to provide a liquid crystal display device and an organic electroluminescent device.

As a result of intensive studies on the objects, the present inventors have found that the objects can be accomplished by the following configurations.

(1) A laminate comprising: two substrates; and a polarizing plate disposed between the two substrates,

in which the polarizing plate has a polarizer and a phase difference layer,

the phase difference layer is a layer formed of a composition containing a reciprocal wavelength dispersible liquid crystal compound,

one of the two substrates is a glass substrate having a Na₂O content of 5% by mass or less, and

the other of the two substrates is a glass substrate having a Na₂O content of 5% by mass or less, an inorganic compound film having a moisture permeability of 10⁻³ g/m²·day or less and a thickness of less than 1 μm, or an organic-inorganic hybrid film having a moisture permeability of 10⁻³ g/m²·day or less.

(2) The laminate according to (1), in which the polarizer contains a polyvinyl alcohol-based resin.

(3) The laminate according to (1) or (2), in which the reciprocal wavelength dispersible liquid crystal compound is a liquid crystal compound represented by General Formula (II).

(4) The laminate according to any one of (1) to (3), in which a thickness of the polarizer is less than 10 μm.

(5) The laminate according to any one of (1) to (4), in which Re(450) which is an in-plane retardation value of the phase difference layer at a wavelength of 450 nm, Re(550) which is an in-plane retardation value of the phase difference layer at a wavelength of 550 nm, and Re(650) which is an in-plane retardation value of the phase difference layer at a wavelength of 650 nm satisfy a relationship of Re(450)≤Re(550)≤Re(650).

(6) The laminate according to any one of (1) to (5), in which the phase difference layer is a positive A-plate.

(7) The laminate according to any one of (1) to (6), in which the phase difference layer is a λ/4 plate.

(8) The laminate according to any one of (1) to (7), further comprising a polarizer protective film on at least one surface of the polarizer, in which at least one polarizer protective film contains a thermoplastic norbornene-based resin.

(9) A liquid crystal display device comprising the laminate according to any one of (1) to (8).

(10) An organic electroluminescent device comprising the laminate according to any one of (1) to (8).

According to the present invention, it is possible to provide a laminate which has a phase difference layer and has excellent thermal durability.

Moreover, according to the present invention, it is also possible to provide a liquid crystal display device and an organic electroluminescent device.

### BRIEF DESCRIPTION OF THE DRAWINGS

FIG. 1A is a schematic cross-sectional view showing an example of a laminate according to the embodiment of the present invention.

FIG. 1B is a schematic cross-sectional view showing another example of the laminate according to the embodiment of the present invention.

FIG. 1C is a schematic cross-sectional view showing still another example of the laminate according to the embodiment of the present invention.

FIG. 1D is a schematic cross-sectional view showing still another example of the laminate according to the embodiment of the present invention.

### DESCRIPTION OF THE PREFERRED EMBODIMENTS

Hereinafter, a laminate, a liquid crystal display device, and an organic electroluminescent device according to an embodiment of the present invention will be described.

In addition, in the present specification, a numerical range expressed using “to” means a range that includes the preceding and succeeding numerical values of “to” as the lower limit value and the upper limit value, respectively.

Moreover, “orthogonal” and “parallel” with respect to angles mean a range of a strict angle ±10°, and “same” with respect to the angles can be determined based on whether or not the difference is less than 5°.

Furthermore, in the present specification, “visible light” means light at 380 to 780 nm. Moreover, in the present specification, a measurement wavelength is 550 nm unless otherwise specified with respect to the measurement wavelength.

Next, terms used in the present specification will be described.

<Water Content>

In the present specification, a “water content” means a mass obtained by converting, per unit area, an amount of change between an initial mass of the cut sample and a dry mass of the sample after drying at 120° C. for 2 hours.

<Slow Axis>

In the present specification, a “slow axis” means a direction in which the in-plane refractive index is maximum. Moreover, the slow axis of the phase difference layer is intended to mean a slow axis of the entire phase difference layer.

<Tilt Angle>

In the present specification, a “tilt angle” (also referred to as an inclination angle) means an angle formed by a tilted liquid crystal compound and a layer plane, and means the maximum angle among angles formed by a maximum refractive index direction in a refractive index ellipsoid of the liquid crystal compound and a layer plane. Therefore, in a rod-shaped liquid crystal compound having positive optical anisotropy, the inclination angle means an angle formed by a major axis direction, that is, a director direction of the rod-shaped liquid crystal compound and a layer plane. Moreover, in the present invention, an “average inclination angle” means an average value of tilt angles from an inclination angle at an upper interface of the phase difference layer to an inclination angle at a lower interface.

<Re(λ) and Rth(λ)>

Values of an in-plane retardation (Re(λ)) and a thickness-direction retardation (Rth(λ)) refer to values measured using AxoScan OPMF-1 (manufactured by Opto Science, Inc.) with use of light having a measurement wavelength.

Specifically, by inputting an average refractive index ((nx+ny+nz)/3) and a film thickness (d (μm)) to AxoScan OPMF-1, it is possible to calculate:

Slow axis direction(°)

Re(λ)=R0(λ)

Rth(λ)=((nx+ny)/2−nz)×d.

In addition, R0(λ) is expressed in a numerical value calculated with AxoScan OPMF-1, and means Re(λ).

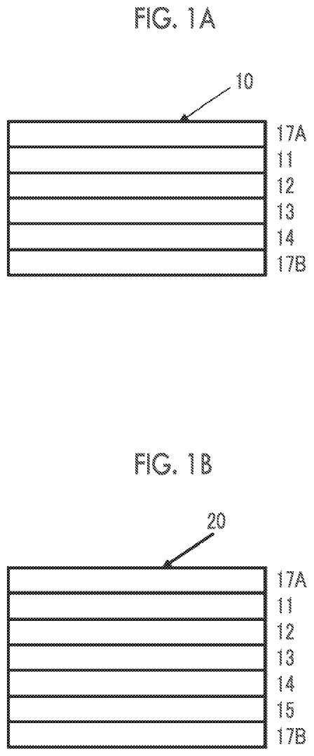

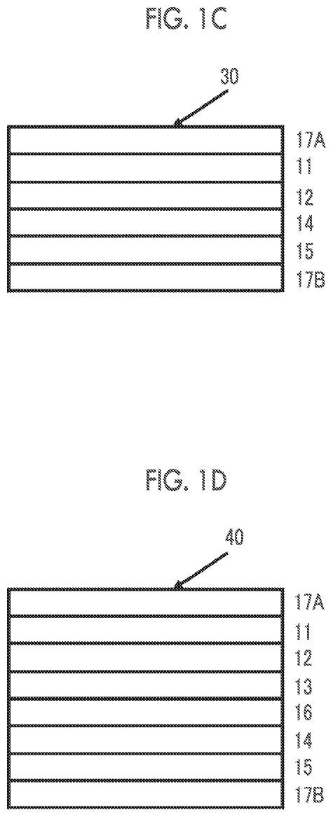

FIG. 1A, FIG. 1B, FIG. 1C, and FIG. 1D are schematic cross-sectional views showing an example of the laminate according to the embodiment of the present invention. Here, a laminate 10 shown in FIG. 1A is a laminate having a layer configuration in which a glass substrate 17A, a polarizer protective film 11, a polyvinyl alcohol polarizer 12, a polarizer protective film 13, a positive A phase difference layer 14, and a glass substrate 17B are provided in this order.

A laminate 20 shown in FIG. 1B is a laminate having a layer configuration in which the glass substrate 17A, the polarizer protective film 11, the polyvinyl alcohol polarizer 12, the polarizer protective film 13, the positive A phase difference layer 14, a positive C phase difference layer 15, and the glass substrate 17B are provided in this order.

A laminate 30 shown in FIG. 1C is a laminate having a layer configuration in which the glass substrate 17A, the polarizer protective film 11, the polyvinyl alcohol polarizer 12, the positive A phase difference layer 14, the positive C phase difference layer 15, and the glass substrate 17B are provided in this order.

A laminate 40 shown in FIG. 1D is a laminate having a layer configuration in which the glass substrate 17A, the polarizer protective film 11, the polyvinyl alcohol polarizer 12, the polarizer protective film 13, a photo-alignment film 16, the positive A phase difference layer 14, the positive C phase difference layer 15, and the glass substrate 17B are provided in this order.

As described above, the laminate according to the embodiment of the present invention takes a form in which a polarizing plate including a polarizer and a phase difference layer is interposed between two glass substrates corresponding to two substrates.

Furthermore, the polyvinyl alcohol polarizer means a polarizer containing a polyvinyl alcohol-based resin as a main component.

The positive A phase difference layer means a phase difference layer which is a positive A-plate. Moreover, the positive C phase difference layer means a phase difference layer which is a positive C-plate.

The glass substrates in FIGS. 1A to 1D each mean a glass substrate having a Na₂O content of 5% by mass or less.

In addition, in FIGS. 1A to 1D, aspects in which two glass substrates are used have been described, but the present invention is not limited to the aspects, and one of the two glass substrates in each drawing may be an inorganic compound film having a moisture permeability of 10⁻³ g/m²·day or less and a thickness of less than 1 μm, or an organic-inorganic hybrid film having a moisture permeability of 10⁻³ g/m²·day or less.

In FIGS. 1A to 1D, it is also preferable that a pressure sensitive adhesive or an adhesive is used for bonding films to each other, but the description of the pressure sensitive adhesive and the adhesive is omitted.

Hereinafter, each member will be described in detail.

<Glass Substrate>

In the laminate according to the embodiment of the present invention, at least one of the two substrates is a glass substrate (hereinafter, also referred to as a “specific glass substrate”) having a Na₂O content of 5% by mass or less. More specifically, one of the two substrates interposing the polarizing plate is a specific glass substrate, and the other may also be a specific glass substrate.

The specific glass substrate is a glass substrate having a Na₂O content of 5% by mass or less with respect to the total mass of the glass substrate. In other words, the specific glass substrate is a glass substrate having a Na₂O content of 5% by mass or less in terms of % by mass on an oxide basis.

In the specific glass substrate, the content of Na₂O may be 5% by mass or less, and, from the viewpoint that the thermal durability of the laminate according to the embodiment of the present invention is superior (hereinafter, also simply referred to as a “viewpoint that the effect of the present invention is superior”), is preferably 4% by mass or less, more preferably 2% by mass or less, and still more preferably 1% by mass or less. The lower limit is not particularly limited, but may be 0% by mass.

The specific glass substrate may contain components other than Na₂O. The specific glass substrate preferably contains SiO₂. In the specific glass substrate, SiO₂ is preferably a main component. Here, the main component means a component with the largest content. Moreover, a content (a content of SiO₂ with respect to the total mass of the specific glass substrate) of SiO₂ in the specific glass substrate is not particularly limited, but, from the viewpoint that the effect of the present invention is superior, is preferably 50% by mass or more, more preferably 60% by mass or more, and still more preferably 75% by mass or more, in terms of % by mass on an oxide basis. The upper limit is not particularly limited, but is 95% by mass or less in many cases.

The specific glass substrate may contain components other than Na₂O and SiO₂, and examples thereof include oxides of atoms other than Na and Si, such as B₂O₃, Al₂O₃, CaO, MgO, K₂O, and Fe₂O₃.

Furthermore, in the specific glass substrate, a content of components (oxides of other atoms) other than Na₂O and SiO₂ with respect to the total mass of the specific glass substrate is not particularly limited, but is preferably 20% by mass or less from the viewpoint that the effect of the present invention is superior. The lower limit is not particularly limited, but may be 0% by mass or more.

That is, the total content of Na₂O and SiO₂ in the specific glass substrate is preferably 80% by mass or more in terms of % by mass on an oxide basis. The upper limit is not particularly limited, but may be 100% by mass.

In addition, main components of soda-lime glass, which is produced in large quantities for industrial use and has a cost advantage, are SiO₂ (content: 65% to 75% by mass), Na₂O (content: 10% to 20% by mass), and CaO (content: 5% to 15% by mass), and the soda-lime glass contains a higher amount of Na₂O compared to the specific glass substrate.

As a glass substrate having a lower Na₂O content compared to the soda-lime glass, borosilicate glass is mentioned. A typical composition of the borosilicate glass is that, with respect to the total mass of the glass, a content of SiO₂ is 68% to 82% by mass, a content of B₂O₃ is 7% to 14% by mass, a content of Na₂O is 3% to 5% by mass, and a content of K₂O is 0% to 3% by mass. An example of the borosilicate glass is PIREX manufactured by Corning Incorporated.

A thickness of the specific glass substrate is not particularly limited, but is preferably 1 μm or greater, more preferably 1 to 2,000 μm, and still more preferably 500 to 1,500 μm.

<Inorganic Compound Film Having Moisture Permeability of 10⁻³ g/m²·Day or Less and Thickness of Less than 1 μm, and Organic-Inorganic Hybrid Film Having Moisture Permeability of 10⁻³ g/m²·Day or Less>

In the laminate according to the embodiment of the present invention, one of the two substrates interposing the polarizing plate may be any one (hereinafter, also simply referred to as a “low-moisture permeability substrate”) of an inorganic compound film having a moisture permeability of 10⁻³ g/m²·day or less and a thickness of less than 1 μm, or an organic-inorganic hybrid film having a moisture permeability of 10⁻³ g/m²·day or less.

A moisture permeability (a moisture permeability of the inorganic compound film having a thickness of less than 1 μm, and a moisture permeability of the organic-inorganic hybrid film) of the low-moisture permeability substrate is 10⁻³ g/m²·day or less. Among them, from the viewpoint of durability of an organic electroluminescent device and a liquid crystal display device, to which the laminate is applied, 10⁻⁴ g/m²·day or less is preferable and 10⁻⁵ g/m²·day or less is more preferable. The lower limit is not particularly limited, but is 10⁻¹⁰ g/m² day or greater in many cases.

A method for measuring the moisture permeability of the low-moisture permeability substrate is as follows. The measurement is performed using a water vapor transmission measuring device (AQUATRAN 2 (registered trademark) manufactured by MOCON, INC.) under the conditions of a measuring temperature of 40° C. and a relative humidity of 90%.

As a method for forming the inorganic compound film having a thickness of less than 1 μm, any method can be used as long as a desired thin layer can be formed by the method. For example, a sputtering method, a vacuum vapor deposition method, an ion plating method, and a plasma chemical vapor deposition (CVD) method are suitable, and specifically, the formation methods described in JP3400324B, JP2002-322561A, and JP2002-361774A can be adopted.

The components contained in the inorganic compound film are not particularly limited as long as the components exhibit a low-moisture permeability function, and for example, oxides, nitrides, oxynitrides, or the like of one or more elements selected from Si, Al, In, Sn, Zn, Ti, Cu, Ce, Ta, and the like can be used. Among them, an oxide, a nitride, or an oxynitride of an element selected from Si, Al, In, Sn, Zn, and Ti is preferable, and an oxide, a nitride, or an oxynitride of an element selected from Si, Al, Sn, and Ti is more preferable. These components may contain other elements as a secondary component.

Furthermore, a film consisting of a reaction product of an aluminum compound and a phosphorus compound, as described in JP2016-040120A and JP2016-155255A, is also preferable.

For example, the organic-inorganic hybrid film may be in a form in which a layer containing an organic material is laminated on an inorganic compound layer, as described in U.S. Pat. No. 6,413,645B, JP2015-226995A, JP2013-202971A, JP2003-335880A, JP1978-012953B (JP-S53-012953B), and JP1983-217344A (JP-S58-217344A), or may be a layer obtained by hybridizing an organic compound and an inorganic compound, as described in WO2011/011836A, JP2013-248832A, and JP3855004B.

A thickness of the inorganic compound film is less than 1 μm, preferably 5 to 500 nm, and more preferably 10 to 200 nm.

A thickness of the organic-inorganic hybrid film is preferably 0.1 to 10 μm and more preferably 0.5 to 5.5 μm.

The low-moisture permeability substrate is preferably transparent, and is preferably a so-called transparent substrate.

Furthermore, in the present specification, “transparent” indicates that a transmittance of visible light is 60% or greater, preferably 80% or greater, and more preferably 90% or greater. The upper limit is not particularly limited, but is less than 100% in many cases.

<Phase Difference Layer>

The laminate has a phase difference layer. The phase difference layer used in the present invention is a layer formed of a composition containing a reciprocal wavelength dispersible liquid crystal compound.

In the following, first, components in the composition used for forming the phase difference layer will be described in detail, and then a manufacturing method and characteristics of the phase difference layer will be described in detail.

Furthermore, in the present specification, the reciprocal wavelength dispersible liquid crystal compound refers to a compound in which in a case where an in-plane retardation (Re) value at a specific wavelength (visible light range) of the phase difference layer manufactured using a reciprocal wavelength dispersible liquid crystal compound is measured, the Re value is the same or increased as a measurement wavelength is increased, and refers to a compound satisfying a relationship of Re(450)≤Re(550)≤Re(650) as will be described later.

The liquid crystal compound is susceptible to decomposition by water, and in a case where, among liquid crystal compounds, the reciprocal wavelength dispersible liquid crystal compound is used, this problem tends to be remarkable.

Specifically, the inventors have found that in a case where the phase difference layer manufactured using the reciprocal wavelength dispersible liquid crystal compound is exposed under the condition of a high temperature, decomposition of a structure derived from the reciprocal wavelength dispersible liquid crystal compound in the phase difference layer is rapidly caused after a certain induction period, and a variation in the in-plane retardation value is increased. The reason for this is presumed to be the following phenomenon.

That is, as one method for causing the reciprocal wavelength dispersible liquid crystal compound to have reciprocal wavelength dispersibility, there is a method for imparting electron-withdrawing properties. It is presumed that by doing so, positive polarization of carbon atoms constituting the reciprocal wavelength dispersible liquid crystal compound is increased and the liquid crystal compound is more susceptible to attack by a nucleophile (estimated to be water).

Since the polarizing plate is interposed between predetermined substrates such as a glass substrate, the Re change in a high-temperature environment, which is a problem of the present invention, is considered to be caused by a minute amount of moisture originally contained in a polarizing plate (for example, a polyvinyl alcohol-based resin in the polarizer) as a supply source of moisture. Moreover, a hydrolysis reaction occurs in the phase difference layer formed of the reciprocal wavelength dispersible liquid crystal compound, but due to the hydrophobic environment, moisture of a reactive factor is little, and the rate limiting of the hydrolysis reaction is considered to be the amount of moisture supplied.

It is presumed that in an end part of the polarizing plate, moisture of the supply source is diffused in an in-plane direction before the hydrolysis reaction occurs, the moisture is diffused from an end surface of the laminate to the outside of the laminate, and consumed, and thus an amount of moisture supplied to the phase difference layer is also reduced and the hydrolysis reaction does not occur, whereas in a central part of the polarizing plate, the hydrolysis reaction occurs earlier than the diffusion of moisture of the supply source in the in-plane direction, and thus a variation in the in-plane retardation value is caused.

In a case where a glass substrate having a high Na₂O content is used, it is presumed that Na ions eluted from the glass substrate may promote the hydrolysis reaction of the reciprocal wavelength dispersible liquid crystal compound.

In the present invention, it is presumed that by using a glass substrate having a Na₂O content which is lower than a predetermined value, the promotion of the hydrolysis reaction is suppressed, and as a result, a laminate exhibiting a desired effect is obtained.

(Composition)

The composition (hereinafter, also simply referred to as a “composition”) used for forming the phase difference layer of the present invention contains the reciprocal wavelength dispersible liquid crystal compound.

In addition, the reciprocal wavelength dispersible liquid crystal compound preferably has a polymerizable group.

A type of the polymerizable group is not particularly limited, and examples thereof include an acryloyl group, a methacryloyl group, a vinyl group, a styryl group, and an allyl group.

A type of the reciprocal wavelength dispersible liquid crystal compound is not particularly limited, but can be classified into a rod-shaped type (rod-shaped liquid crystal compound) and a disk-shaped type (disk-shaped liquid crystal compound, discotic liquid crystal compound) according to the shape thereof. Furthermore, each liquid compound has a low-molecular-weight type and a high-molecular-weight type. In general, “high-molecular-weight” indicates that a degree of polymerization is 100 or higher (Polymer Physics—Phase Transition Dynamics, written by Masao DOI, page 2, Iwanami Shoten, Publishers, 1992). In the present invention, any liquid crystal compound can be used.

Among them, it is preferable to use a rod-shaped liquid crystal compound. This is because there is an advantage that the formed phase difference film easily functions as a positive A-plate by homogeneously (horizontally) aligning the rod-shaped liquid crystal compounds.

The reciprocal wavelength dispersible liquid crystal compound is not particularly limited as long as the compound can form a phase difference layer having reciprocal wavelength dispersibility as described above, and examples thereof include the compound (in particular, the compound described in paragraphs [0034] to [0039]) which is represented by General Formula (I) and is described in JP2008-297210A, the compound (in particular, the compound described in paragraphs [0067] to [0073]) which is represented by General Formula (1) and described in JP2010-084032A, and a liquid crystal compound which is represented by General Formula (II) and will be described later.

As the reciprocal wavelength dispersible liquid crystal compound, the liquid crystal compound represented by General Formula (II) is preferable from the viewpoint that reciprocal wavelength dispersibility is superior.

L₁-G₁-D₁-Ar-D₂-G₂-L₂ (II)

In General Formula (II), D₁ and D₂ each independently represent a single bond, —O—, —CO—O—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—.

R¹, R², R³, and R⁴ each independently represent a hydrogen atom, a fluorine atom, or an alkyl group having 1 to 4 carbon atoms. In a case where a plurality of R¹'s, R²'s, R³'s, and R⁴'s are present, the plurality of R¹'s, the plurality of R²'s, the plurality of R³'s, and the plurality of R⁴'s may be the same as or different from each other, respectively.

G₁ and G₂ each independently represent a divalent alicyclic hydrocarbon group having 5 to 8 carbon atoms, or a divalent aromatic hydrocarbon group having 5 to 8 carbon atoms, and a methylene group contained in the alicyclic hydrocarbon group may be substituted with —O—, —S—, or —NH—.

L₁ and L₂ each independently represent a monovalent organic group, and at least one selected from the group consisting of L₁ and L₂ represents a monovalent group having a polymerizable group.

Ar represents a divalent aromatic ring group represented by General Formula (II-1), General Formula (II-2), General Formula (II-3), or General Formula (II-4). In General Formulae (II-1) to (II-4), * represents a bonding position.

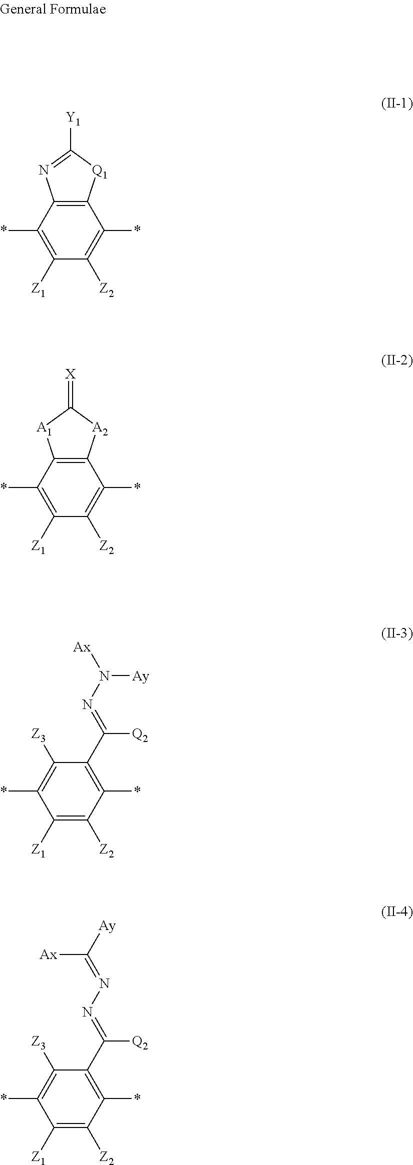

In General Formulae (II-1) to (II-4), Q₁ represents —S—, —O—, or —NR¹¹—,

R¹¹ represents a hydrogen atom or an alkyl group having 1 to 6 carbon atoms,

Y₁ represents an aromatic hydrocarbon group having 6 to 12 carbon atoms or an aromatic heterocyclic group having 3 to 12 carbon atoms (furthermore, the aromatic hydrocarbon group and the aromatic heterocyclic group may each have a substituent),

Z₁, Z₂, and Z₃ each independently represent a hydrogen atom, an aliphatic hydrocarbon group having 1 to 20 carbon atoms, an alicyclic hydrocarbon group having 3 to 20 carbon atoms, a monovalent aromatic hydrocarbon group having 6 to 20 carbon atoms, a halogen atom, a cyano group, a nitro group, —NR¹²R¹³, or —SR¹²,

Z₁ and Z₂ may be bonded to each other to form an aromatic ring or an aromatic heterocyclic ring, and R¹² and R¹³ each independently represent a hydrogen atom or an alkyl group having 1 to 6 carbon atoms,

A₁ and A₂ are each independently a group selected from the group consisting of —O—, —NR²¹—, —S—, and —CO—, where R²¹ represents a hydrogen atom or a substituent, and X represents a hydrogen atom or a non-metallic atom (preferred examples thereof include ═O, ═S, ═NR′, and ═C(R′)R′ (where R′ represents a substituent, and examples of the substituent represented by R′ include a cyano group or —CO₂R (R represents an alkyl group))) of Groups 14 to 16, to which a substituent may be bonded,

Ax represents an organic group having 2 to 30 carbon atoms and having at least one aromatic ring selected from the group consisting of an aromatic hydrocarbon ring and an aromatic heterocyclic ring, and preferred examples thereof include: an aromatic hydrocarbon ring group; an aromatic heterocyclic group; an alkyl group having 3 to 20 carbon atoms and having at least one aromatic ring selected from the group consisting of an aromatic hydrocarbon ring and an aromatic heterocyclic ring; and an alkenyl group having 3 to 20 carbon atoms and having at least one aromatic ring selected from the group consisting of an aromatic hydrocarbon ring and an aromatic heterocyclic ring,

Ay represents a hydrogen atom, an alkyl group which has 1 to 6 carbon atoms and may have a substituent, or an organic group which has 2 to 30 carbon atoms and has at least one aromatic ring selected from the group consisting of an aromatic hydrocarbon ring and an aromatic heterocyclic ring, and suitable aspects of this organic group are the same as the suitable aspects of the organic group represented by Ax,

the aromatic rings in Ax and Ay may each have a substituent, and Ax and Ay may be bonded to each other to form a ring, and

Q₂ represents a hydrogen atom, or an alkyl group which has 1 to 6 carbon atoms and may have a substituent.

Furthermore, examples of the substituent that each group exemplified above may have include a halogen atom, an alkyl group, a halogenated alkyl group, an alkenyl group, an aryl group, a cyano group, an amino group, a nitro group, a nitroso group, a carboxy group, an alkylsulfinyl group having 1 to 6 carbon atoms, an alkylsulfonyl group having 1 to 6 carbon atoms, a fluoroalkyl group having 1 to 6 carbon atoms, an alkoxy group having 1 to 6 carbon atoms, an alkylsulfanyl group having 1 to 6 carbon atoms, an N-alkylamino group having 1 to 6 carbon atoms, an N,N-dialkylamino group having 2 to 12 carbon atoms, an N-alkylsulfamoyl group having 1 to 6 carbon atoms, an N,N-dialkylsulfamoyl group having 2 to 12 carbon atoms, or a group obtained by combining these substituents.

For the definition and the preferred range of each substituent of the liquid crystal compound represented by General Formula (II), reference can be made to the description on D¹, D², G¹, G², L¹, L², R⁴, R⁵, R⁶, R⁷, Y¹, Q¹, and Q² for the compound (A) described in JP2012-021068A with regard to D₁, D₂, G₁, G₂, L₁, L₂, R¹, R², R³, R⁴, Q₁, Y₁, Z₁, and Z₂, respectively; reference can be made to the description on A₁, A₂, and X for the compound represented by General Formula (I) described in JP2008-107767A with regard to A₁, A₂, and X, respectively; and reference can be made to the description on Ax, Ay, and Q¹ for the compound represented by General Formula (I) described in WO2013/018526A with regard to Ax, Ay, and Q₂, respectively. Reference can be made to the description on Q¹ for the compound (A) described in JP2012-021068A with regard to Z₃.

In particular, the organic groups represented by L₁ and L₂ are each preferably a group represented by -D₃-G₃-Sp-P₃.

D₃ has the same meaning as D₁.

G₃ represents a single bond, a divalent aromatic ring group having 6 to 12 carbon atoms, a divalent heterocyclic group having 6 to 12 carbon atoms, or a divalent alicyclic hydrocarbon group having 5 to 8 carbon atoms, and a methylene group included in the alicyclic hydrocarbon group may be substituted with —O—, —S—, or —NR¹—, where R⁷ represents a hydrogen atom or an alkyl group having 1 to 6 carbon atoms.

Sp represents a single bond, or a spacer group represented by —(CH₂)ₙ—, —(CH₂)ₙ—O—, —(CH₂—O—)ₙ—, —(CH₂CH₂—O—)ₘ, —O—(CH₂)ₙ—, —O—(CH₂)ₙ—O—, —O—(CH₂—O—)ₙ—, —O—(CH₂CH₂—O—)ₘ, —C(═O)—O—(CH₂)ₙ—, —C(═O)—O—(CH₂)ₙ—O—, —C(═O)—O—(CH₂—O—)ₙ—, —C(═O)—O—(CH₂CH₂—O—)ₘ, —C(═O)—N(R⁸)—(CH₂)ₙ—, —C(═O)—N(R⁸)—(CH₂)ₙ—O—, —C(═O)—N(R⁸)—(CH₂—O—)ₙ—, —C(═O)—N(R⁸)—(CH₂CH₂—O—)ₘ, or —(CH₂)ₙ—O—(C═O)—(CH₂)ₙ—C(═O)—O—(CH₂)ₙ—. Here, n represents an integer of 2 to 12, m represents an integer of 2 to 6, and R⁸ represents a hydrogen atom or an alkyl group having 1 to 6 carbon atoms. Moreover, the hydrogen atom of —CH₂— in each of the above groups may be substituted with a methyl group.

P₃ represents a polymerizable group.

The polymerizable group is not particularly limited, but is preferably a polymerizable group capable of radical polymerization or cationic polymerization.

As a radically polymerizable group, known radically polymerizable groups are mentioned, and an acryloyl group or a methacryloyl group is preferable. It is known that the acryloyl group generally has a high polymerization rate, from the viewpoint of improvement in productivity, the acryloyl group is preferable, but the methacryloyl group can also be similarly used as the polymerizable group of a high birefringence liquid crystal.

As a cationically polymerizable group, known cationically polymerizable groups are mentioned, and examples thereof include an alicyclic ether group, a cyclic acetal group, a cyclic lactone group, a cyclic thioether group, a spiroorthoester group, and a vinyloxy group. Among them, an alicyclic ether group or a vinyloxy group is preferable, and an epoxy group, an oxetanyl group, or a vinyloxy group is more preferable.

Particularly preferred examples of the polymerizable group include the following groups.

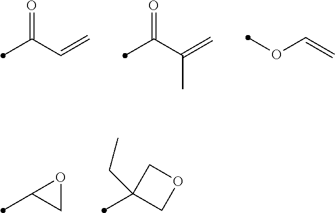

Furthermore, in the present specification, the “alkyl group” may be any one of linear, branched, or cyclic, and examples thereof include a methyl group, an ethyl group, an n-propyl group, an isopropyl group, an n-butyl group, an isobutyl group, a sec-butyl group, a tert-butyl group, an n-pentyl group, an isopentyl group, a neopentyl group, a 1,1-dimethylpropyl group, an n-hexyl group, an isohexyl group, a cyclopropyl group, a cyclobutyl group, a cyclopentyl group, and a cyclohexyl group.

In particular, from the viewpoint that the effect of the present invention is superior, an aspect in which Ar³ in General Formula (III) is a divalent aromatic ring group represented by General Formula (II-1), or an aspect in which Ar³ in General Formula (III) is a divalent aromatic ring group represented by General Formula (II-3), and at least one of D₁ or D₂ is a group other than —CO—O— (for example, a single bond, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—) is preferable.

Preferred examples of the liquid crystal compound represented by General Formula (II) are shown below, but are not limited to these liquid crystal compounds.

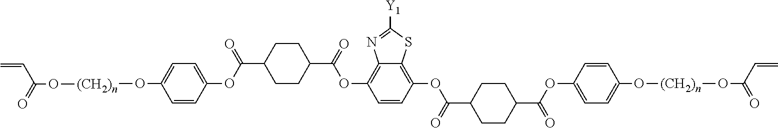

| No | Y₁ | n |
|---|---|---|
| II-1-1 | 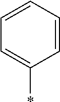 [SMILES: *c1ccccc1] | 6 |
| II-1-2 | 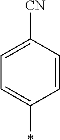 [SMILES: *c1ccc(C#N)cc1] | 6 |
| II-1-3 | 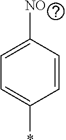 | 6 |
| II-1-4 | 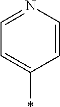 [SMILES: *c1ccncc1] | 6 |
| II-1-5 | 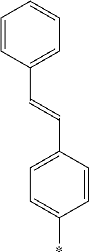 [SMILES: *c1ccc(/C=C/c2ccccc2)cc1] | 6 |
| II-1-6 | 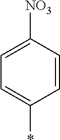 | 11 |
| II-1-7 | 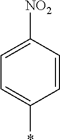 [SMILES: *c1ccc([N+](=O)[O-])cc1] | 8 |
| II-1-8 | 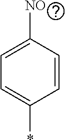 | 4 |
| II-1-9 | 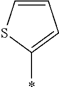 [SMILES: *c1cccs1] | 6 |
| II-1-10 | 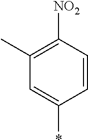 [SMILES: *c1ccc([N+](=O)[O-])c(C)c1] | 6 |
| II-1-11 | 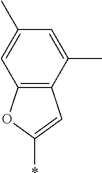 [SMILES: *c1cc2c(C)cc(C)cc2o1] | 6 |
| II-1-12 | 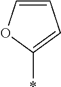 [SMILES: *c1ccco1] | 6 |
| II-1-13 | 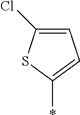 [SMILES: *c1ccc(Cl)s1] | 6 |
| II-1-14 | 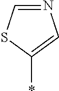 [SMILES: *c1cncs1] | 6 |
| II-1-15 | 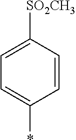 [SMILES: *c1ccc(S(C)(=O)=O)cc1] | 6 |

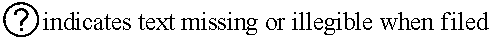

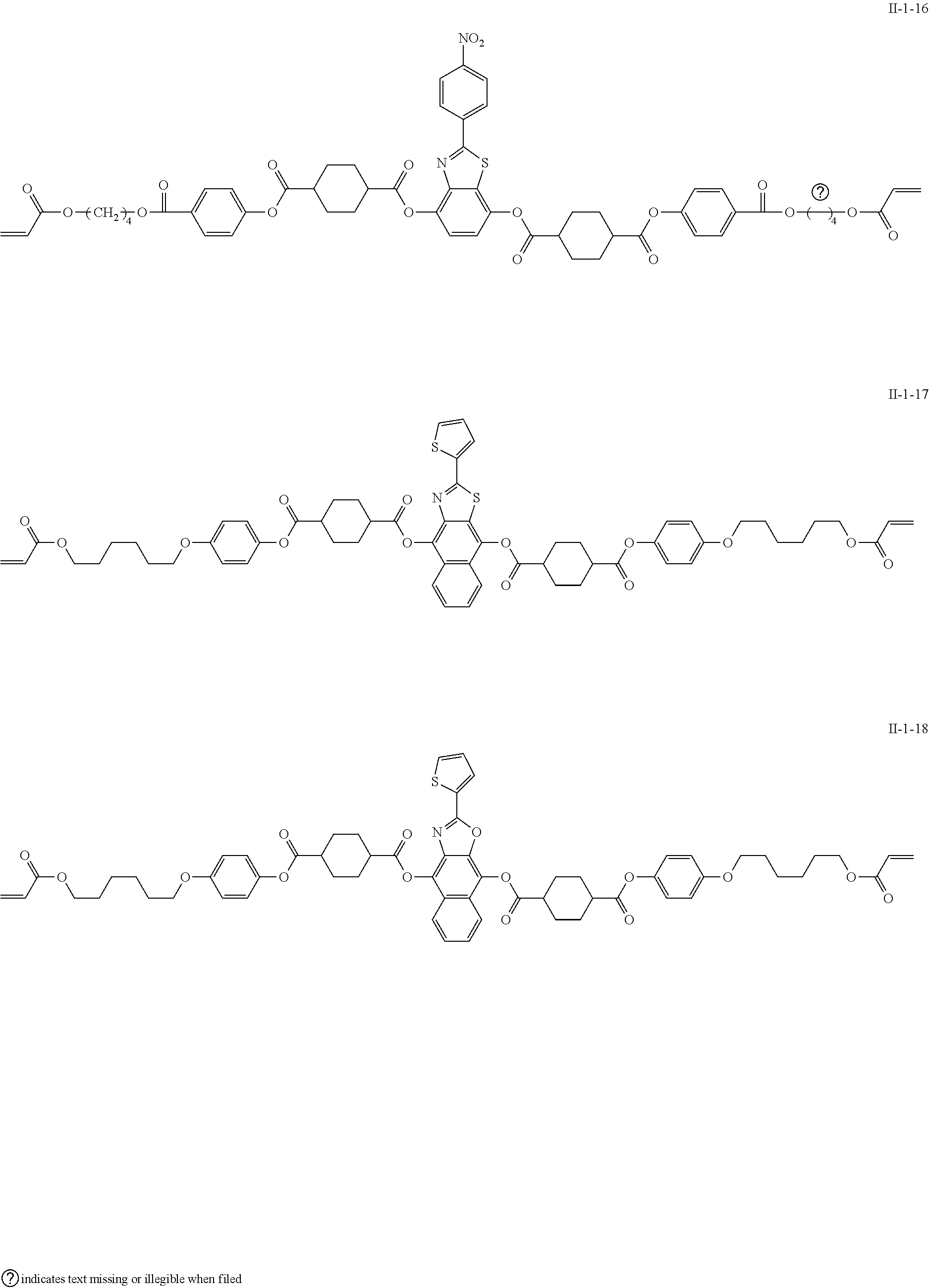

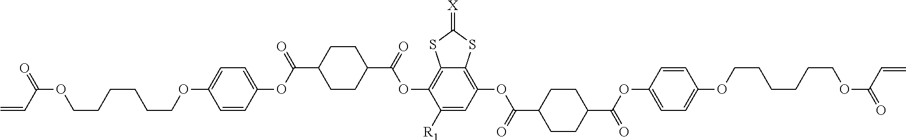

| No | X | R₁ |
|---|---|---|
| II-2-1 | 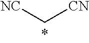 | H |
| II-2-2 | 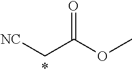 | H |
| II-2-3 | 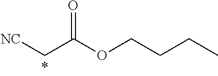 | H |
| II-2-4 | 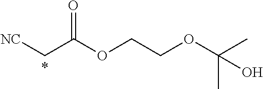 | H |
| II-2-5 | 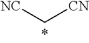 | CH₃ |
| II-2-6 | 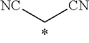 | 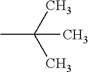 |
| II-2-7 | S | H |

Furthermore, in the formulae, “*” represents a bonding position.

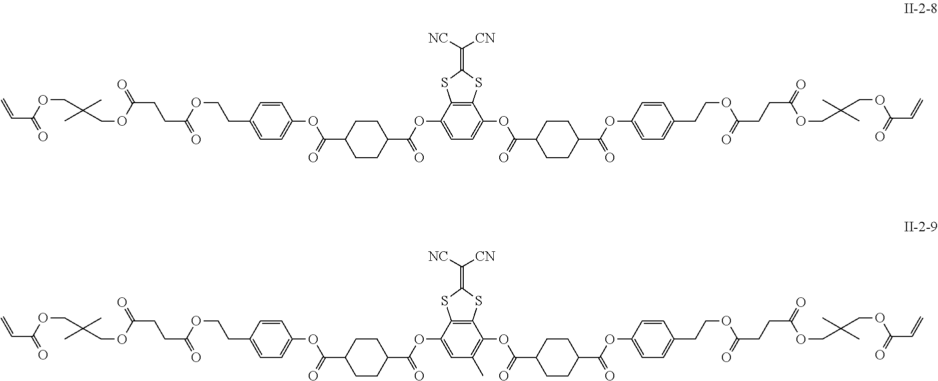

In addition, the group adjacent to the acryloyloxy group in Formulae II-2-8 and II-2-9 represents a propylene group (a group in which a methyl group is substituted with an ethylene group), and represents a mixture of positional isomers having methyl groups at different positions.

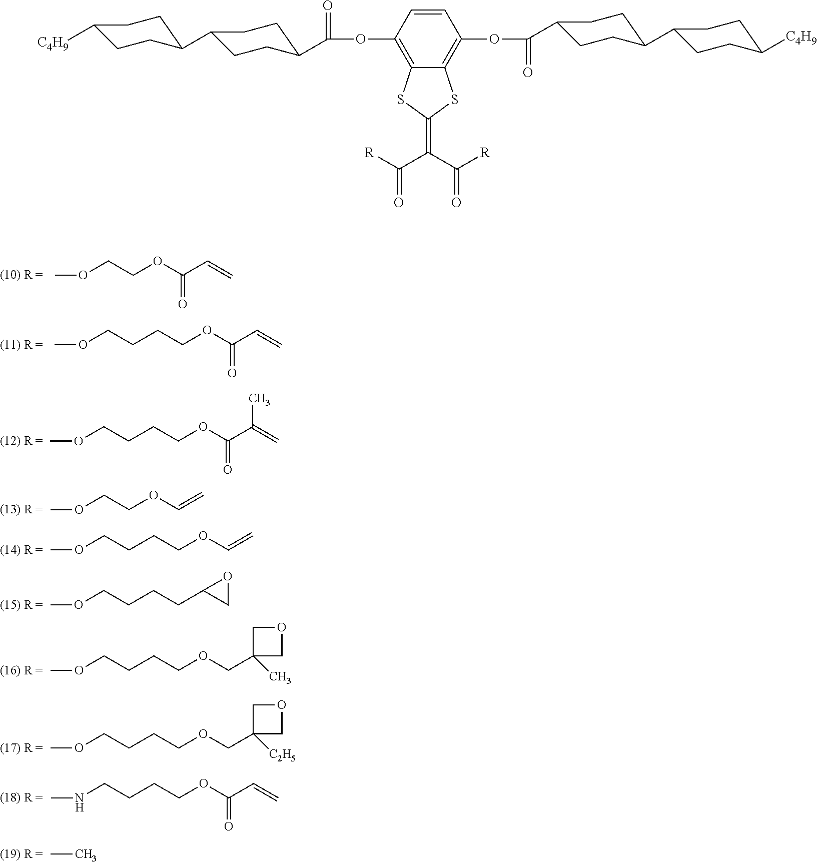

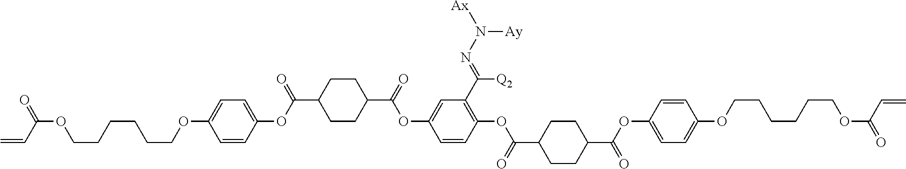

| No | Ax | Ay | Q₂ |
|---|---|---|---|
| II-3-1 | 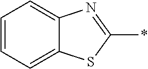 [SMILES: *c1nc2ccccc2s1] | H | H |
| II-3-2 | 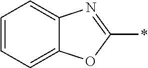 [SMILES: *c1nc2ccccc2o1] | H | H |
| II-3-3 | 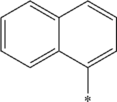 [SMILES: *c1cccc2ccccc12] | H | H |
| II-3-4 | Ph | Ph | H |
| II-3-5 | 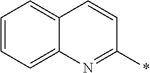 [SMILES: *c1ccc2ccccc2n1] | H | H |
| II-3-6 | 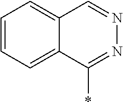 [SMILES: *c1nncc2ccccc12] | H | H |
| II-3-7 | 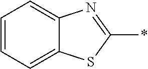 [SMILES: *c1nc2ccccc2s1] | CH₃ | H |
| II-3-8 | 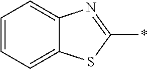 [SMILES: *c1nc2ccccc2s1] | C₄H₉ | H |
| II-3-9 | 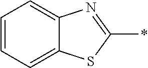 [SMILES: *c1nc2ccccc2s1] | C₆H₁₃ | H |
| II-3-10 | 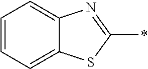 [SMILES: *c1nc2ccccc2s1] | 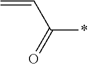 [SMILES: *C(=O)C=C] | H |
| II-3-11 | 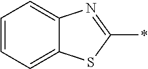 [SMILES: *c1nc2ccccc2s1] | 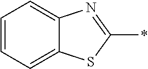 [SMILES: *c1nc2ccccc2s1] | H |
| II-3-12 | 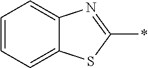 [SMILES: *c1nc2ccccc2s1] | CH₃CN | H |
| II-3-13 | 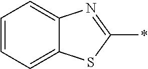 [SMILES: *c1nc2ccccc2s1] | 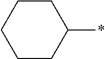 [SMILES: *C1CCCCC1] | H |
| II-3-14 | 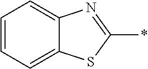 [SMILES: *c1nc2ccccc2s1] | 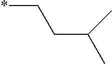 [SMILES: *CCC(C)C] | H |
| II-3-15 | 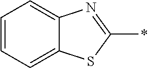 [SMILES: *c1nc2ccccc2s1] | CH₂CH₂OH | H |
| II-3-16 | 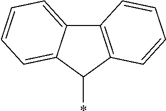 [SMILES: *C1c2ccccc2-c2ccccc21] | H | H |
| II-3-17 | 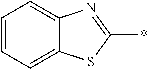 [SMILES: *c1nc2ccccc2s1] | CH₂CF₃ | H |
| II-3-18 | 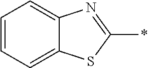 [SMILES: *c1nc2ccccc2s1] | H | CH₃ |
| II-3-19 | 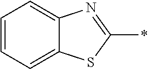 [SMILES: *c1nc2ccccc2s1] | 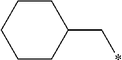 [SMILES: *CC1CCCCC1] | H |
| II-3-20 | 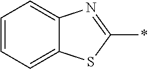 [SMILES: *c1nc2ccccc2s1] | 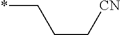 [SMILES: *CCCC#N] | H |
| II-3-21 | 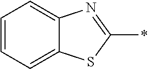 [SMILES: *c1nc2ccccc2s1] | 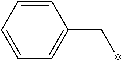 [SMILES: *Cc1ccccc1] | H |
| II-3-22 | 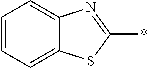 [SMILES: *c1nc2ccccc2s1] | 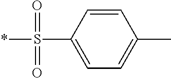 [SMILES: *S(=O)(=O)c1ccc(C)cc1] | H |
| II-3-23 | 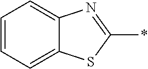 [SMILES: *c1nc2ccccc2s1] | 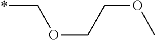 [SMILES: *COCCOC] | H |
| II-3-24 | 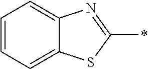 [SMILES: *c1nc2ccccc2s1] | 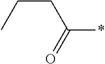 [SMILES: *C(=O)CCC] | H |
| II-3-25 | 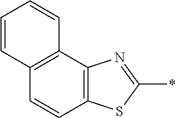 [SMILES: *c1nc2c(ccc3ccccc32)s1] | C₆H₁₃ | H |

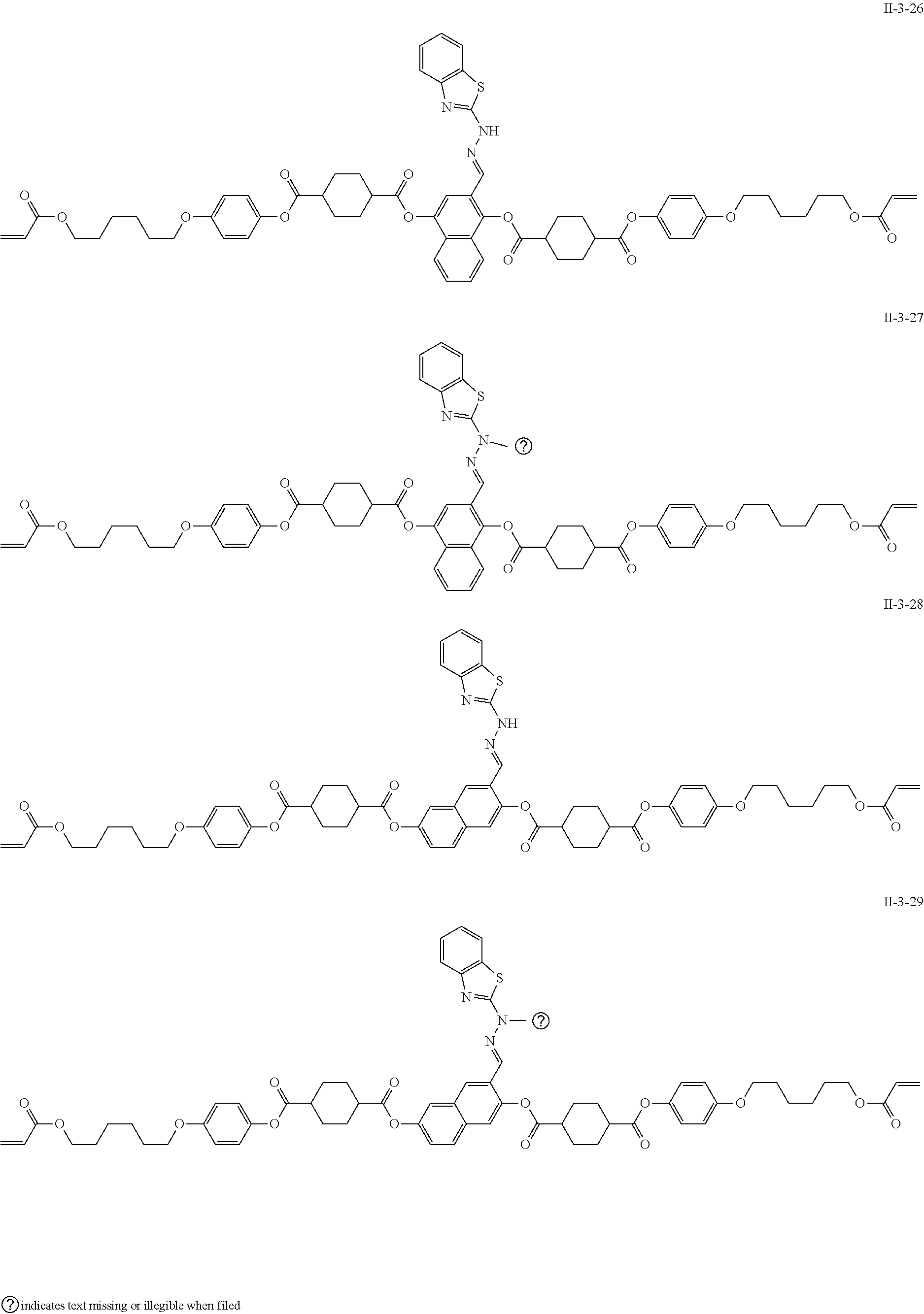

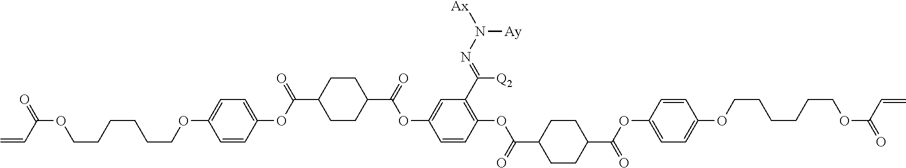

| No | Ax | Ay | Q₂ |
|---|---|---|---|
| II-3-1 | 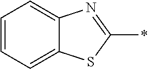 [SMILES: *c1nc2ccccc2s1] | H | H |
| II-3-2 | 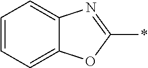 [SMILES: *c1nc2ccccc2o1] | H | H |
| II-3-3 | 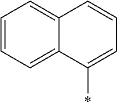 [SMILES: *c1cccc2ccccc12] | H | H |
| II-3-4 | Ph | Ph | H |
| II-3-5 | 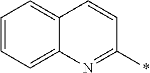 [SMILES: *c1ccc2ccccc2n1] | H | H |
| II-3-6 | 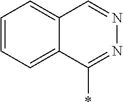 [SMILES: *c1nncc2ccccc12] | H | H |
| II-3-7 | 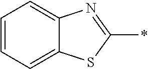 [SMILES: *c1nc2ccccc2s1] | CH₃ | H |
| II-3-8 | 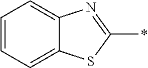 [SMILES: *c1nc2ccccc2s1] | C₄H₉ | H |
| II-3-9 | 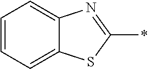 [SMILES: *c1nc2ccccc2s1] | C₆H₁₃ | H |
| II-3-10 | 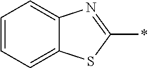 [SMILES: *c1nc2ccccc2s1] | 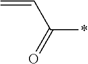 [SMILES: *C(=O)C=C] | H |
| II-3-11 | 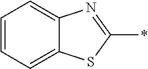 [SMILES: *c1nc2ccccc2s1] | 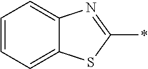 [SMILES: *c1nc2ccccc2s1] | H |
| II-3-12 | 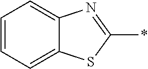 [SMILES: *c1nc2ccccc2s1] | CH₃CN | H |
| II-3-13 | 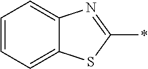 [SMILES: *c1nc2ccccc2s1] | 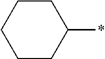 [SMILES: *C1CCCCC1] | H |
| II-3-14 | 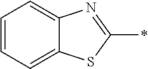 [SMILES: *c1nc2ccccc2s1] | 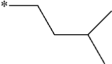 [SMILES: *CCC(C)C] | H |
| II-3-15 | 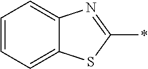 [SMILES: *c1nc2ccccc2s1] | CH₂CH₂OH | H |
| II-3-16 | 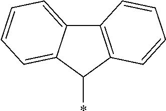 [SMILES: *C1c2ccccc2-c2ccccc21] | H | H |
| II-3-17 | 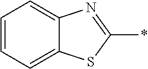 [SMILES: *c1nc2ccccc2s1] | CH₂CF₃ | H |
| II-3-18 | 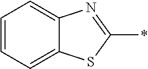 [SMILES: *c1nc2ccccc2s1] | H | CH₃ |
| II-3-19 | 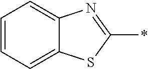 [SMILES: *c1nc2ccccc2s1] | 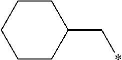 [SMILES: *CC1CCCCC1] | H |
| II-3-20 | 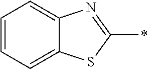 [SMILES: *c1nc2ccccc2s1] | 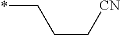 [SMILES: *CCCC#N] | H |
| II-3-21 | 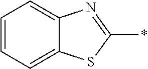 [SMILES: *c1nc2ccccc2s1] | 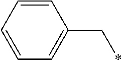 [SMILES: *Cc1ccccc1] | H |
| II-3-22 | 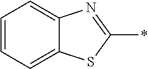 [SMILES: *c1nc2ccccc2s1] | 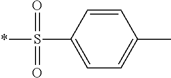 [SMILES: *S(=O)(=O)c1ccc(C)cc1] | H |
| II-3-23 | 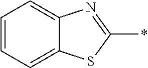 [SMILES: *c1nc2ccccc2s1] | 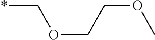 [SMILES: *COCCOC] | H |
| II-3-24 | 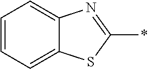 [SMILES: *c1nc2ccccc2s1] | 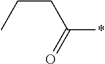 [SMILES: *C(=O)CCC] | H |
| II-3-25 | 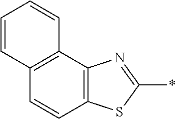 [SMILES: *c1nc2c(ccc3ccccc32)s1] | C₆H₁₃ | H |

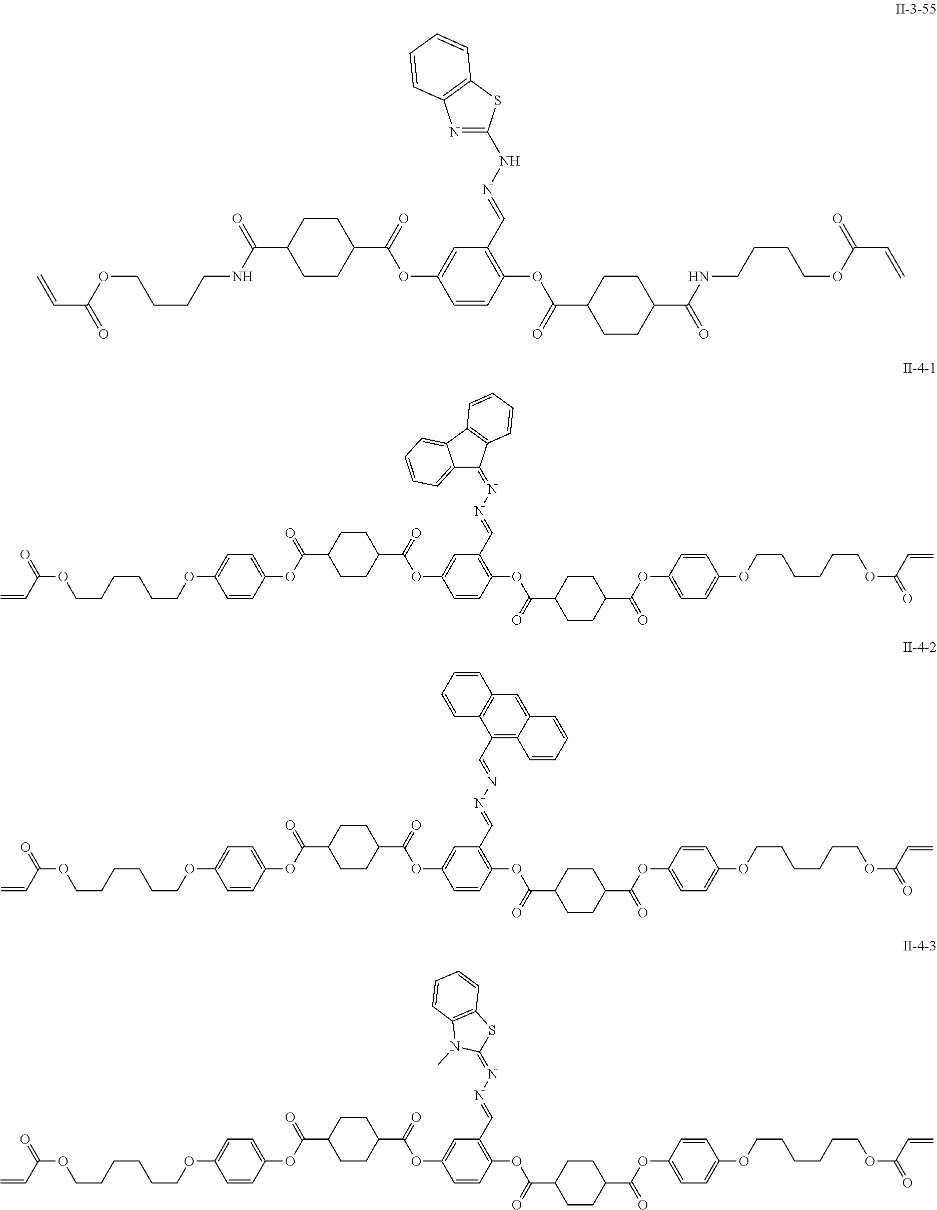

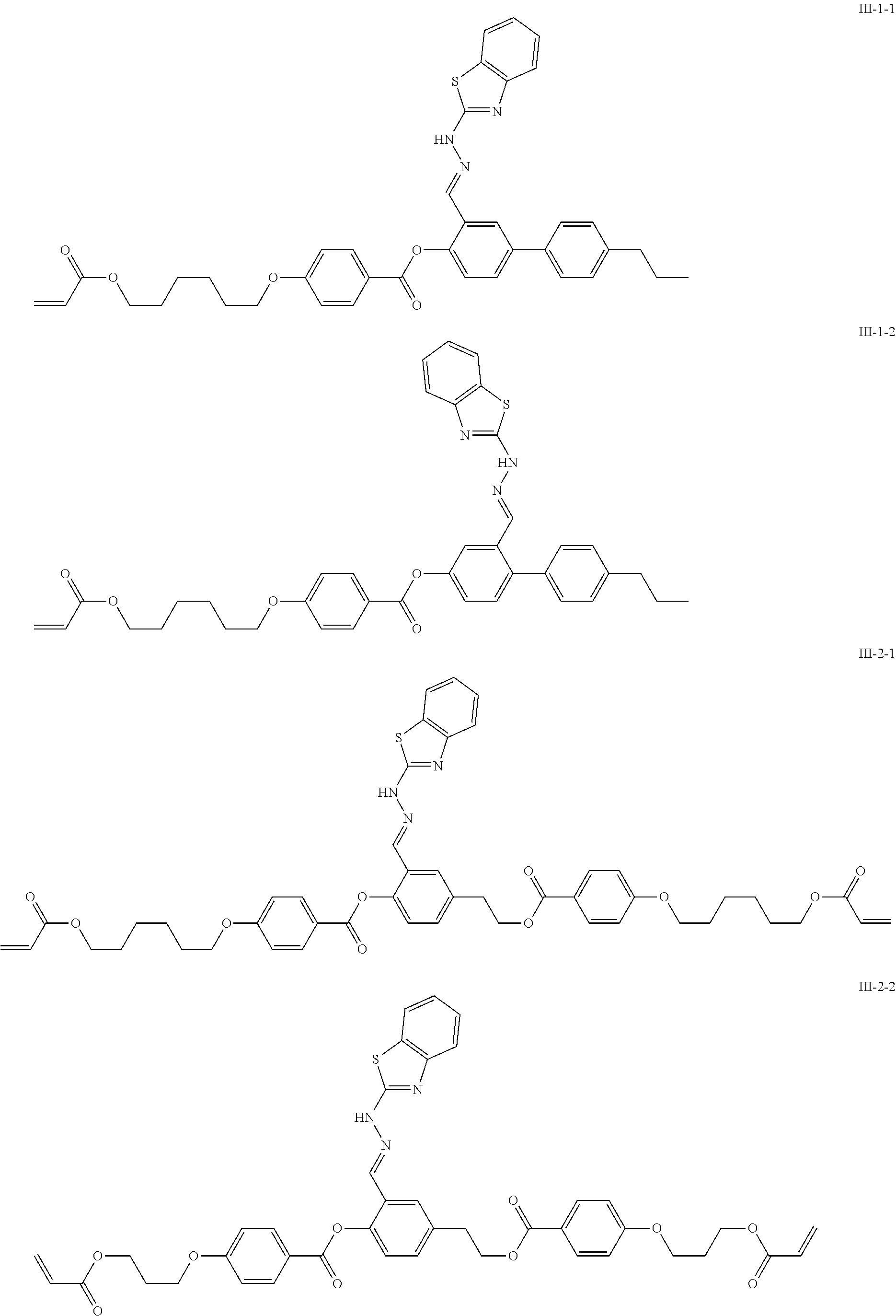

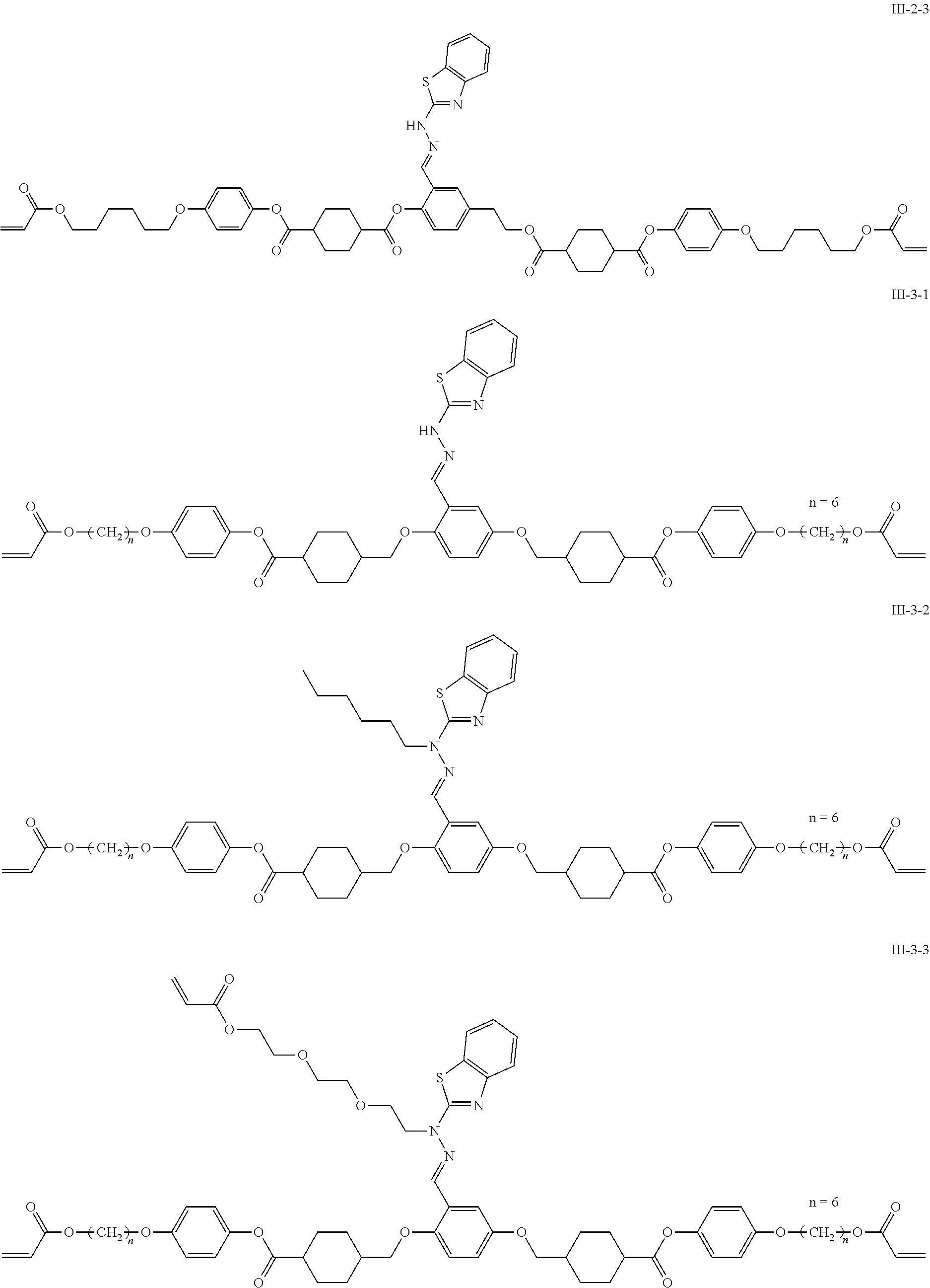

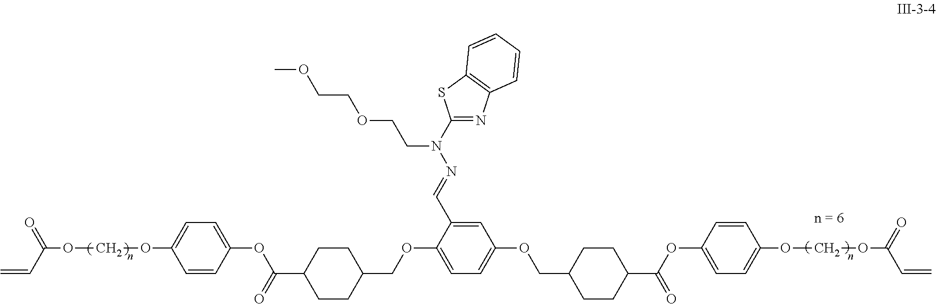

A content of the reciprocal wavelength dispersible liquid crystal compound (for example, the liquid crystal compound represented by General Formula (II)) in the composition is not particularly limited, but is preferably 60% to 100% by mass, more preferably 70% to 100% by mass, and still more preferably 70% to 90% by mass with respect to the total solid content in the composition. In a case where the content is 70% by mass or more, the reciprocal wavelength dispersibility is superior.

The solid content means other components excluding a solvent in the composition, and the other components are calculated as the solid content even in a case where a property of the components is a liquid.

The composition may contain a polymerizable rod-shaped compound in addition to the reciprocal wavelength dispersible liquid crystal compound. The polymerizable rod-shaped compound may or may not have liquid crystallinity. By adding the polymerizable rod-shaped compound, liquid crystal alignability of the reciprocal wavelength dispersible liquid crystal compound can be controlled.

Since the polymerizable rod-shaped compound is mixed with the reciprocal wavelength dispersible liquid crystal compound and treated as a polymerizable composition, a polymerizable rod-shaped compound having high compatibility with the reciprocal wavelength dispersible liquid crystal compound is preferable.

A content of the polymerizable rod-shaped compound in the composition is preferably 0% to 30% by mass and more preferably 0% to 20% by mass with respect to the total mass of the reciprocal wavelength dispersible liquid crystal compound.

As the polymerizable rod-shaped compound, a compound partially having a cyclohexane ring in which one hydrogen atom is substituted with a linear alkyl group is preferable.

Here, the “cyclohexane ring in which one hydrogen atom is substituted with a linear alkyl group” refers to a cyclohexane ring in which one hydrogen atom of the cyclohexane ring present on a terminal side of a molecule is substituted with a linear alkyl group, for example, in a case where the compound has two cyclohexane rings as shown in General Formula (2).

Examples of the polymerizable rod-shaped compound include compounds having a structure represented by General Formula (2), and among them, from the viewpoint that the effect of the present invention is superior, a compound which is represented by General Formula (3) and has a (meth)acryloyl group, is preferable.

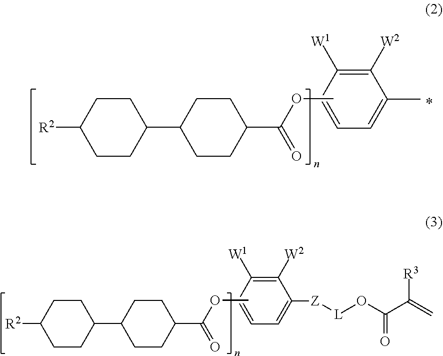

Here, * in General Formula (2) represents a bonding position.

In addition, in General Formulae (2) and (3), R² represents an alkyl group having 1 to 10 carbon atoms, n represents 1 or 2, W¹ and W² each independently represent an alkyl group, an alkoxy group, or a halogen atom, and W¹ and W² may be bonded to each other to form a ring structure which may have a substituent.

Furthermore, in General Formula (3), Z represents —COO— or —OCO—, L represents an alkylene group having 1 to 6 carbon atoms, and R³ represents a hydrogen atom or a methyl group.

Examples of such a compound include compounds represented by Formulae A-1 to A-5. Moreover, in Formula A-3, R⁴ represents an ethyl group or a butyl group.

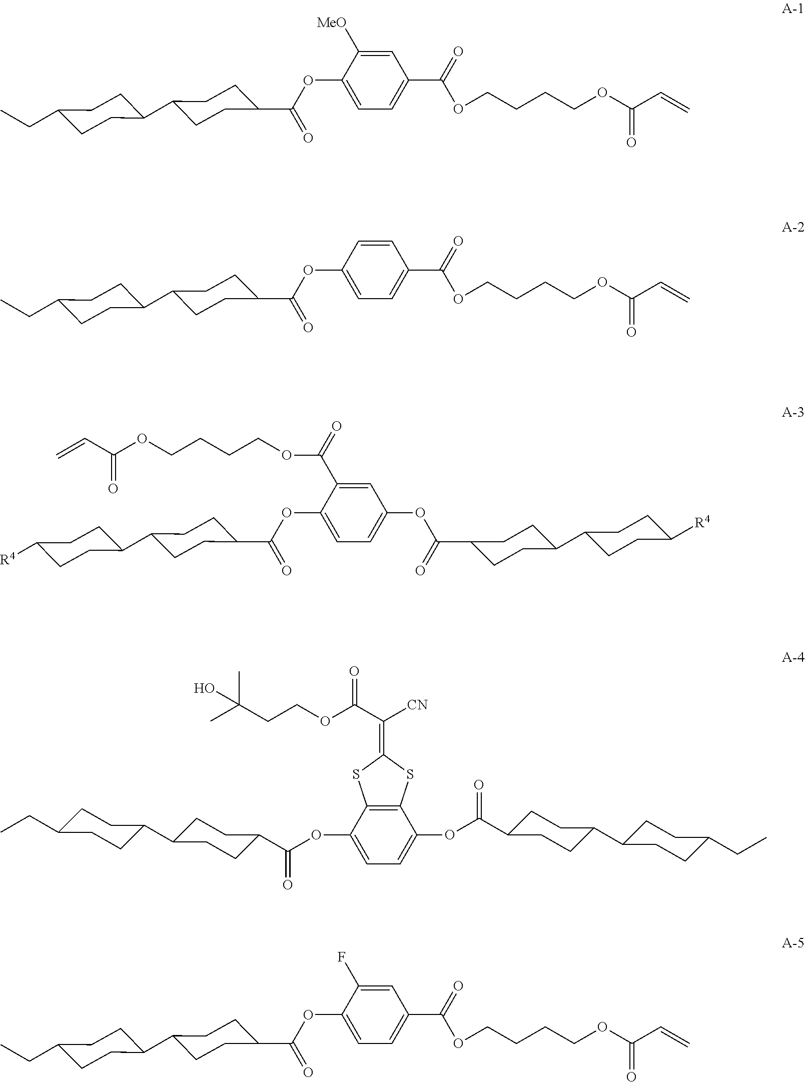

The composition may contain another polymerizable liquid crystal compound in addition to the reciprocal wavelength dispersible liquid crystal compound.

A polymerizable group of the polymerizable liquid crystal compound is not particularly limited, and examples thereof include a (meth)acryloyl group, a vinyl group, a styryl group, and an allyl group. Among them, a (meth)acryloyl group is preferable.

From the viewpoint that the effect of the present invention is superior, the other polymerizable liquid crystal compound is preferably a polymerizable liquid crystal compound having two to four polymerizable groups, and more preferably a polymerizable liquid crystal compound having two polymerizable groups.

Examples of such a polymerizable liquid crystal compound include the compounds which are represented by Formulae (M1), (M2), and (M3) and described in paragraphs [0030] to [0033] of JP2014-077068A, and more specific examples thereof include the specific examples described in paragraphs [0046] to [0055] of JP2014-077068A.

The polymerizable liquid crystal compounds may be used alone or in combination of two or more thereof.

A content of the other polymerizable liquid crystal compound in a case where the composition contains the other polymerizable liquid crystal compound is not particularly limited, but is preferably 0 to 40 parts by mass and more preferably 0 to 10 parts by mass with respect to 100 parts by mass of the total of the reciprocal wavelength dispersible liquid crystal compound and the other polymerizable liquid crystal compound.

The composition may contain non-liquid crystal polyfunctional polymerizable compound from the viewpoint that the effect of the present invention is superior. It is presumed that this is because movement of a compound serving as a catalyst for a hydrolysis reaction is suppressed by increasing a density of a crosslinking point, and as a result, a rate of the hydrolysis reaction slows down, during which diffusion of moisture to the end part of the laminate progresses.

Meanwhile, the non-liquid crystal polyfunctional polymerizable compound may cause disorder of liquid crystal alignment, and thus a compound having a low acrylic equivalent is preferable. The acrylic equivalent is preferably 120 or lower, more preferably 100 or lower, and still more preferably 90 or lower. Here, the acrylic equivalent is obtained by dividing a molecular weight by the number of acrylic functional groups.

Examples of the non-liquid crystal polyfunctional polymerizable compound include ester of polyhydric alcohol and (meth)acrylic acid (for example, ethylene glycol di(meth)acrylate, 1,4-cyclohexane diacrylate, pentaerythritol tetra(meth)acrylate, pentaerythritol tri(meth)acrylate, trimethylolpropane tri(meth)acrylate, trimethylolethane tri(meth)acrylate, dipentaerythritol tetra(meth)acrylate, dipentaerythritol penta(meth)acrylate, dipentaerythritol hexa(meth)acrylate, 1,2,3-cyclohexane tetramethacrylate, polyurethane polyacrylate, and polyester polyacrylate), vinylbenzene and a derivative thereof (for example, 1,4-divinylbenzene, 4-vinylbenzoic acid-2-acryloylethyl ester, and 1,4-divinylcyclohexanone), vinyl sulfone (for example, divinyl sulfone), acrylamide (for example, methylenebisacrylamide), and methacrylamide.

However, development of the phase difference of the phase difference layer is attenuated by increasing the content of the non-liquid crystal polyfunctional polymerizable compound, and thus the content of the non-liquid crystal polyfunctional polymerizable compound with respect to the total solid content in the composition is preferably 0.1% to 20% by mass, more preferably 0.1% to 10% by mass, and still more preferably 0.1% to 5% by mass, or the content is preferably 1% to 20% by mass, more preferably 1% to 10% by mass, and still more preferably 1% to 5% by mass.

(Polymerization Initiator)

The composition may contain a polymerization initiator.

The polymerization initiator to be used is preferably a photopolymerization initiator capable of initiating a polymerization reaction upon irradiation with ultraviolet rays.

Examples of the photopolymerization initiator include the α-carbonyl compound (described in each of the specifications of U.S. Pat. Nos. 2,367,661A and 2,367,670A), the acyloin ether (described in the specification of U.S. Pat. No. 2,448,828A), the α-hydrocarbon-substituted aromatic acyloin compound (described in the specification of U.S. Pat. No. 2,722,512A), the polynuclear quinone compound (described in each of the specifications of U.S. Pat. Nos. 3,046,127A and 2,951,758A), the combination of a triarylimidazole dimer and p-aminophenyl ketone (described in the specification of U.S. Pat. No. 3,549,367A), the acridine and phenazine compounds (described in JP1985-105667A (JP-S60-105667A) and the specification of U.S. Pat. No. 4,239,850A), the oxadiazole compound (described in the specification of U.S. Pat. No. 4,212,970A), and the acyl phosphine oxide compounds (described in JP1988-040799B (JP-S63-040799B), JP1993-029234B (JP-H05-029234B), JP1998-095788A (JP-H10-095788A), and JP1998-029997A (JP-H10-029997A)).

From the viewpoint that the effect of the present invention is superior, the polymerization initiator is preferably an oxime-type polymerization initiator, and more preferably a polymerization initiator represented by General Formula (III).

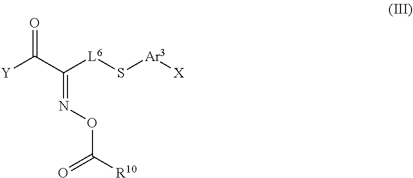

Here, in General Formula (III), X represents a hydrogen atom or a halogen atom, and Y represents a monovalent organic group.

Moreover, Ar³ represents a divalent aromatic group, L⁶ represents a divalent organic group having 1 to 12 carbon atoms, and R¹⁰ represents an alkyl group having 1 to 12 carbon atoms.

Examples of the halogen atom represented by X in General Formula (III) include a fluorine atom, a chlorine atom, a bromine atom, and an iodine atom, and a chlorine atom is preferable.

Examples of the divalent aromatic group represented by Ar³ in General Formula (III) include a divalent group having: an aromatic hydrocarbon ring such as a benzene ring, a naphthalene ring, an anthracene ring, and a phenanthroline ring; or an aromatic heterocyclic ring such as a furan ring, a pyrrole ring, a thiophene ring, a pyridine ring, a thiazole ring, and a benzothiazole ring.

Examples of the divalent organic group which has 1 to 12 carbon atoms and is represented by L⁶ in General Formula (III) include a linear or branched alkylene group having 1 to 12 carbon atoms, and specific examples thereof include a methylene group, an ethylene group, and a propylene group.

Specific examples of the alkyl group which has 1 to 12 carbon atoms and is represented by R¹⁰ in General Formula (III) include a methyl group, an ethyl group, and a propyl group.

Examples of the monovalent organic group represented by Y in General Formula (III) include a functional group including a benzophenone skeleton ((C₆H₅)₂CO). Specifically, as in the groups represented by General Formula (3a) and General Formula (3b), a functional group including a benzophenone skeleton in which a benzene ring at a terminal is unsubstituted or mono-substituted is preferable.

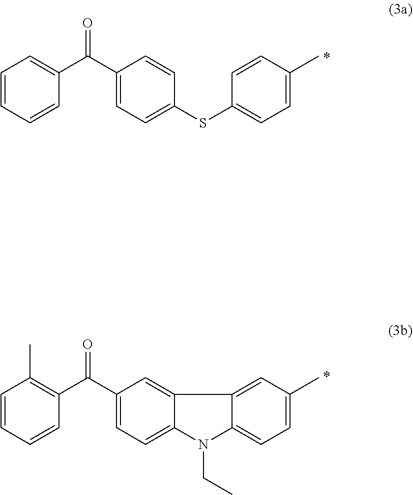

Here, in General Formula (3a) and General Formula (3b), * represents a bonding position, that is, a bonding position to the carbon atom of the carbonyl group in General Formula (III).

Examples of the oxime-type polymerization initiator represented by General Formula (III) include a compound represented by Formula S-1 and a compound represented by Formula S-2.

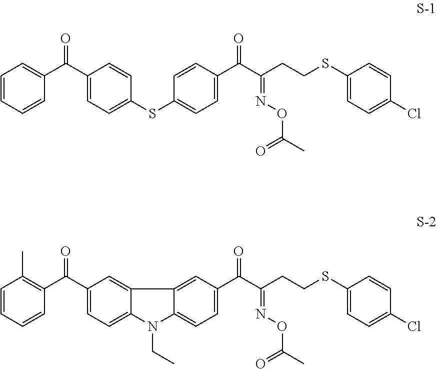

A content of the polymerization initiator is not particularly limited, but the content of the polymerization initiator is preferably 0.5 to 10 parts by mass and more preferably 1 to 5 parts by mass with respect to 100 parts by mass of the reciprocal wavelength dispersible liquid crystal compound contained in the composition.

(Alignment Control Agent)

The composition may contain an alignment control agent. By using the alignment control agent, for example, a homogeneous alignment state where the liquid crystal compounds are aligned parallel to a surface of a layer can be attained.

As the alignment control agent, for example, a low-molecular-weight alignment control agent or a high-molecular-weight alignment control agent can be used. With regard to the low-molecular-weight alignment control agent, reference can be made to the description in, for example, paragraphs [0009] to [0083] of JP2002-020363A, paragraphs [0111] to [0120] of JP2006-106662A, and paragraphs [0021] to [0029] of JP2012-211306A, the contents of which are incorporated herein by reference. Moreover, with regard to the high-molecular-weight alignment control agent, reference can be made to the description in, for example, paragraphs [0021] to [0057] of JP2004-198511A and paragraphs [0121] to [0167] of JP2006-106662A, the contents of which are incorporated herein by reference.

A content of the alignment control agent is not particularly limited, but the content of the alignment control agent is preferably 0.01% to 10% by mass and more preferably 0.05% to 5% by mass with respect to the total solid content in the composition.

(Solvent)

The composition preferably contains a solvent from the viewpoint of workability for forming the phase difference layer or the like. Examples of the solvent include water and an organic solvent.

Examples of the solvent include ketones (for example, acetone, 2-butanone, methyl ethyl ketone, methyl isobutyl ketone, cyclohexanone, cyclopentanone, and the like), ethers (for example, dioxane, tetrahydrofuran, and the like), aliphatic hydrocarbons (for example, hexane and the like), alicyclic hydrocarbons (for example, cyclohexane and the like), aromatic hydrocarbons (for example, toluene, xylene, trimethylbenzene, and the like), halocarbons (for example, dichloromethane, dichloroethane, dichlorobenzene, chlorotoluene, and the like), esters (for example, methyl acetate, ethyl acetate, butyl acetate, and the like), water, alcohols (for example, ethanol, isopropanol, butanol, cyclohexanol, and the like), cellosolves (for example, methyl cellosolve, ethyl cellosolve, and the like), cellosolve acetates, sulfoxides (for example, dimethyl sulfoxide and the like), and amides (for example, dimethylformamide, dimethylacetamide, and the like), and these solvents may be used alone or in combination of two or more thereof.

(Other Components)

The composition may contain components other than the above-mentioned components, and examples thereof include liquid crystal compounds other than the above-mentioned liquid crystal compounds, a leveling agent, a surfactant, an inclination angle controlling agent, an alignment aid, a plasticizer, and a crosslinking agent.

(Method for Manufacturing Phase Difference Layer)

A method for manufacturing the phase difference layer used in the present invention is not particularly limited, and known methods are mentioned.

For example, a phase difference layer can be manufactured by applying the composition to a predetermined substrate (for example, a support layer which will be described later) to form a coating film, and subjecting the obtained coating film to a curing treatment (irradiation with active energy rays (light irradiation treatment) and/or heating treatment). Moreover, an alignment film, which will be described later, may be used, as desired.

Application of the composition can be carried out by known methods (for example, a wire bar coating method, an extrusion coating method, a direct gravure coating method, a reverse gravure coating method, and a die-coating method).

In the method for manufacturing the phase difference layer, it is preferable that an alignment treatment for a reciprocal wavelength dispersible liquid crystal compound contained in the coating film is performed before performing the curing treatment on the coating film. By doing so, the obtained phase difference layer is easily made into a positive A-plate which will be described later.

The alignment treatment can be performed by drying at room temperature (for example, 20° C. to 25° C.) or the like, or heating. In a case of a thermotropic liquid crystal compound, a liquid crystal phase formed by the alignment treatment can be generally transitioned by a change in a temperature or pressure. In a case of a liquid crystal compound having a lyotropic property, the transition can be performed also by a compositional ratio such as an amount of a solvent.

For example, in a case where the rod-shaped liquid crystal compound exhibits a smectic phase, the temperature range in which a nematic phase is exhibited is generally higher than the temperature range in which the rod-shaped liquid crystal compound exhibits the smectic phase. Therefore, in a case where the reciprocal wavelength dispersible liquid crystal compound exhibits the smectic phase, the reciprocal wavelength dispersible liquid crystal compound can be transitioned from the nematic phase to the smectic phase by heating the reciprocal wavelength dispersible liquid crystal compound to the temperature range in which the nematic phase is exhibited, and then lowering the heating temperature to the temperature range in which the reciprocal wavelength dispersible liquid crystal compound exhibits the smectic phase. By such a method, a positive A-plate in which the reciprocal wavelength dispersible liquid crystal compounds are aligned with a high degree of order can be obtained.

In a case where the alignment treatment is a heating treatment, a heating time (heat-aging time) is preferably 10 seconds to 5 minutes, more preferably 10 seconds to 3 minutes, and still more preferably 10 seconds to 2 minutes.

The above-mentioned curing treatment (irradiation with active energy rays (light irradiation treatment) and/or heating treatment) for the coating film can also be referred to as a fixing treatment for fixing the alignment of the reciprocal wavelength dispersible liquid crystal compounds.

The fixing treatment is preferably performed by irradiation with active energy rays (preferably, ultraviolet rays), and the liquid crystal is fixed by polymerization of the reciprocal wavelength dispersible liquid crystal compound.

(Characteristics of Phase Difference Layer)

The phase difference layer is a layer formed of the above-mentioned composition. Optical characteristics of the phase difference layer are not particularly limited, but it is preferable that the phase difference layer functions as a λ/4 plate.

The λ/4 plate is a plate having a function of converting linearly polarized light having a specific wavelength to circularly polarized light (or converting circularly polarized light to linearly polarized light), and refers to a plate (optically anisotropic layer) whose in-plane retardation Re(λ) at a specific wavelength of λ nm satisfies Re(λ)=λ/4.

This expression may be achieved at any wavelength (for example, 550 nm) in the visible light range, but the in-plane retardation Re(550) at a wavelength of 550 nm preferably satisfies a relationship of 110 nm≤Re(550)≤160 nm and more preferably satisfies 110 nm≤Re(550)≤150 nm.

It is preferable that Re(450) which is an in-plane retardation of the phase difference layer at a wavelength of 450 nm, Re(550) which is an in-plane retardation of the phase difference layer at a wavelength of 550 nm, and Re(650) which is an in-plane retardation of the phase difference layer at a wavelength of 650 nm have a relationship of Re(450)≤Re(550)≤Re(650). That is, this relationship can be said to be a relationship indicating reciprocal wavelength dispersibility.

A method for measuring the in-plane retardation value at each wavelength is as described above.

Furthermore, a range of Re(550)/Re(450) is not particularly limited, but is preferably 1.05 to 1.25 and more preferably 1.10 to 1.23. Moreover, a range of Re(650)/Re(550) is not particularly limited, but is preferably 1.01 to 1.25 and more preferably 1.01 to 1.10.

The phase difference layer may be an A-plate or a C-plate, and is preferably a positive A-plate.

The phase difference layer may have a single-layered structure or a multi-layer structure. In a case of the multi-layer structure, the A-plate (for example, a positive A-plate) and the C-plate (for example, a positive C-plate) may be laminated.

In addition, in the present specification, a positive A-plate is defined as follows. In a case where a refractive index in a slow axis direction (direction in which the in-plane refractive index is maximum) in a film plane is defined as nx, a refractive index in a direction orthogonal to an in-plane slow axis in a plane is defined as ny, and a refractive index in the thickness direction is defined as nz, the positive A-plate satisfies a relationship of Expression (A1). Moreover, in the positive A-plate, Rth shows a positive value.

nx>ny≈nz Expression (A1)

Furthermore, the symbol “≈” encompasses not only a case where the both are completely the same as each other but also a case where the both are substantially the same as each other. For example, “being substantially the same” indicates that a case where (ny−nz) ×d (provided that d is a thickness of a film) is −10 to 10 nm and preferably −5 to 5 nm is also included in “ny≈nz”.

The positive A-plate can be obtained by horizontally aligning rod-shaped polymerizable liquid crystal compounds such as the above-mentioned composition. With regard to the details of the method for manufacturing the positive A-plate, reference can be made to the description in, for example, JP2008-225281A, JP2008-026730A, and the like.

In addition, in the present specification, a positive C-plate is defined as follows. In a case where a refractive index in a slow axis direction (direction in which the in-plane refractive index is maximum) in a film plane is defined as nx, a refractive index in a direction orthogonal to an in-plane slow axis in a plane is defined as ny, and a refractive index in the thickness direction is defined as nz, the positive C-plate satisfies a relationship of Expression (A2). Moreover, in the positive C-plate, Rth shows a negative value.

nx≈ny<nz Expression (A2)

Furthermore, the symbol “≈” encompasses not only a case where the both are completely the same as each other but also a case where the both are substantially the same as each other. For example, “being substantially the same” indicates that a case where (nx−ny)×d (provided that d is a thickness of a film) is −10 to 10 nm and preferably −5 to 5 nm is also included in “nx≈ny”.

Moreover, in the positive C-plate, Re≈0 is satisfied from the above definition.

The positive C-plate can be obtained by vertically aligning rod-shaped polymerizable liquid crystal compounds. With regard to the details of the method for manufacturing the positive C-plate, reference can be made to the description in, for example, JP2017-187732A or JP2016-053709A, JP2015-200861A, and the like.

Furthermore, a thickness of the phase difference layer is not particularly limited, but is preferably 1 to 5 μm, more preferably 1 to 4 μm, and still more preferably 1 to 3 μm.

In addition, a relationship between a transmission axis of the polarizer and a slow axis of the phase difference layer in the laminate is not particularly limited.

In a case where the laminate is applied to antireflection application, it is preferable that the phase difference layer is a λ/4 plate, and an angle formed by the transmission axis of the polarizer and the slow axis of the phase difference layer is in a range of 45°±10° (35° to 55°).

Furthermore, in a case where the laminate is applied to optical compensation application of an oblique viewing angle of an in-plane-switching (IPS) liquid crystal, it is preferable that the phase difference layer has a multi-layer structure of the positive A-plate of the λ/4 plate and the positive C-plate, and the angle formed by the transmission axis of the polarizer and the slow axis of the phase difference layer is in a range of 0°±10° (−10° to 10°) or a range of 90°±10° (80° to 100°).

<Polarizer>

The laminate according to the embodiment of the present invention has a polarizer.

The polarizer (polarizing film) to be used is a so-called linear polarizer having a function of converting light into specific linearly polarized light. The polarizer is not particularly limited, but an absorption-type polarizer can be used.

A type of the polarizer is not particularly limited, known polarizers can be used, and examples thereof include a polarizer containing a polyvinyl alcohol-based resin.

The polyvinyl alcohol-based resin is a resin containing a repeating unit of —CH₂—CHOH—, and examples thereof include polyvinyl alcohol and an ethylene-vinyl alcohol copolymer.

The polyvinyl alcohol-based resin is obtained, for example, by saponifying a polyvinyl acetate-based resin. Examples of the polyvinyl acetate-based resin include copolymers with other monomers copolymerizable with vinyl acetate, in addition to polyvinyl acetate which is a homopolymer of vinyl acetate.

Examples of the other monomers copolymerizable with vinyl acetate include unsaturated carboxylic acids, olefins, vinyl ethers, unsaturated sulfonic acids, and acrylamides having an ammonium group.

A saponification degree of the polyvinyl alcohol-based resin is not particularly limited, but is preferably 85% to 100% by mole and more preferably 95.0% to 99.95% by mole. The saponification degree can be determined according to JIS K 6726-1994.

An average degree of polymerization of the polyvinyl alcohol-based resin is not particularly limited, but is preferably 100 to 10,000 and more preferably 1,500 to 8,000. Similar to the saponification degree, the average degree of polymerization can be determined according to JIS K 6726-1994.

A content of the polyvinyl alcohol-based resin in the polarizer is not particularly limited, but it is preferable that the polyvinyl alcohol-based resin is contained as a main component in the polarizer. The main component means that the content of the polyvinyl alcohol-based resin is 50% by mass or more with respect to the total mass of the polarizer. The content of the polyvinyl alcohol-based resin is preferably 90% by mass or more with respect to the total mass of the polarizer. The upper limit is not particularly limited, but is 99.9% by mass or less in many cases.

The polarizer preferably further contains a dichroic substance. Examples of the dichroic substance include iodine and an organic dye (dichroic organic dye). That is, it is preferable that the polarizer contains polyvinyl alcohol as a main component and also contains a dichroic substance.

A method for manufacturing the polarizer is not particularly limited, known methods can be mentioned, and examples thereof include a method for adsorbing a dichroic substance to a substrate containing polyvinyl alcohol and stretching the resultant.

In addition, examples of a polarizer other than the polarizer containing a polyvinyl alcohol-based resin include a coating-type polarizer manufactured by application or the like using a liquid crystal compound and a dichroic azo coloring agent (for example, a dichroic azo coloring agent used for the light-absorbing anisotropic film described in WO2017-195833A), as described in WO2017-195833A and JP2017-083843A.

A thickness of the polarizer is not particularly limited, but is preferably 1 to 20 μm, more preferably 1 to 15 μm, still more preferably 1 to 10 μm, and particularly preferably 1 to 5 μm. By reducing the thickness of the polarizer, not only reduction in the thickness of the display device but also further reduction in the water content is possible, and thus the thermal durability can be further improved. The thickness of the polarizer is preferably less than 10 μm from the viewpoint that the above characteristics are superior.

<Other Layers>

The laminate according to the embodiment of the present invention may have other members in addition to the substrate, the phase difference layer, and the polarizer, which are mentioned above.

Furthermore, the polarizing plate included in the laminate includes the phase difference layer and the polarizer. Moreover, as will be described later, the polarizing plate may include a polarizer protective film.

A water content of the polarizing plate is not particularly limited, but is preferably 3 g/m² or less, more preferably 2.3 g/m² or less, still more preferably 1.5 g/m² or less, and most preferably 0.8 g/m² or less.

(Support Layer)

The laminate may have a support layer for supporting the phase difference layer. The support layer is preferably transparent, and specifically, a support layer having a light transmittance of 80% or greater is preferable. Examples of such a support include a polymer film.

A thickness of the support layer is not particularly limited, but is preferably 5 to 80 μm and more preferably 10 to 40 μm.

(Alignment Film)

The laminate may have an alignment film (alignment layer) having a function of defining the alignment direction of the liquid crystal compound.

The alignment film is a film (layer) provided on one surface of the phase difference layer, and is positioned between the support layer and the phase difference layer in a case where the phase difference layer includes the support layer.

In order to form the positive A-plate which is one aspect of the phase difference layer, a technique for causing the molecules of the liquid crystal compound to be in a desired alignment state is used, and for example, a technique for aligning the liquid crystal compounds in a desired direction using the alignment film is generally used.

Examples of the alignment film include a rubbing-treated film of a layer containing an organic compound such as a polymer, an oblique vapor deposition film of an inorganic compound, a film having microgrooves, and a film formed by accumulating a Langmuir-Blodgett (LB) films of organic compounds, such as w-tricosanoic acid, dioctadecylmethylammonium chloride, and methyl stearate, according to an LB method. Moreover, an alignment film or the like in which an alignment function is generated by light irradiation can also be mentioned.

As the alignment film, a film formed by subjecting a surface of a layer (polymer layer) containing an organic compound such as a polymer to a rubbing treatment is preferable. The rubbing treatment is carried out by rubbing the surface of the polymer layer several times with paper or cloth in a certain direction (preferably, the longitudinal direction of the support). Examples of the polymer used for forming the alignment film include polyimide, polyvinyl alcohol, the modified polyvinyl alcohol described in paragraphs [0071] to [0095] of JP3907735B, and the polymer which has a polymerizable group and is described in JP1997-152509A (JP-H09-152509A).

A thickness of the alignment film is not particularly limited, but is preferably 0.01 to 5 μm and more preferably 0.05 to 2 μm.

It is also preferable that a so-called photo-alignment film (photo-alignment layer), which is an alignment film obtained by irradiating a photo-alignment material with polarized light or non-polarized light, is used as the alignment film. It is preferable to impart an alignment regulating force to the photo-alignment film by a step of radiating polarized light from a vertical direction or an oblique direction, or a step of radiating non-polarized light from an oblique direction.

By using the photo-alignment film, it is possible to horizontally align the liquid crystal compounds with excellent symmetry. Therefore, the positive A-plate formed by using the photo-alignment film is particularly useful for optical compensation in a liquid crystal display device which does not require a pre-tilt angle of a drive liquid crystal, such as a liquid crystal display device in an in-plane-switching (IPS) mode.

Examples of the photo-alignment material used for a photo-alignment film include the azo compounds described in JP2006-285197A, JP2007-076839A, JP2007-138138A, JP2007-094071A, JP2007-121721A, JP2007-140465A, JP2007-156439A, JP2007-133184A, JP2009-109831A, JP3883848B, and JP4151746B, the aromatic ester compound described in JP2002-229039A, the maleimide and/or alkenyl-substituted nadimide compounds having photo-alignment units described in JP2002-265541A and JP2002-317013A, the photocrosslinkable silane derivatives described in JP4205195B and JP4205198B, the photocrosslinkable polyimides, polyamides, and esters described in JP2003-520878A, JP2004-529220A, and JP4162850B, and the photodimerizable compounds, in particular, a cinnamate compound, a chalcone compound, and a coumarin compound, described in JP1997-118717A (JP-H09-118717A), JP1998-506420A (JP-H10-506420A), JP2003-505561A, WO2010/150748A, JP2013-177561A, and JP2014-012823A. Particularly preferred examples of the photo-alignment material include the azo compound, the photocrosslinkable polyimide, the polyamide, the ester, the cinnamate compound, and the chalcone compound.

Furthermore, the support layer and the alignment film may be separately provided as layers performing respective functions, or may be provided as a single layer having both functions.

(Polarizer Protective Film)

The laminate may further have a polarizer protective film. That is, the polarizer protective film may be disposed on at least one surface of the polarizer. The polarizer protective film may be disposed only on one surface (on a surface opposed to a phase difference layer side) of the polarizer, or may be disposed on the both surfaces of the polarizer.

The configuration of the polarizer protective film is not particularly limited, and may be, for example, a so-called transparent support or a so-called hard coat layer, or a laminate of the transparent support and the hard coat layer.

As the hard coat layer, known layers can be used, and for example, a layer obtained by polymerizing and curing polyfunctional monomers may be used.

Furthermore, as the transparent support, known transparent supports can be used, and examples of a material forming the transparent support include a cellulose-based polymer (hereinafter, referred to as cellulose acylate) typified by triacetyl cellulose, a thermoplastic norbornene-based resin (ZEONEX or ZEONOR manufactured by Nippon Zeon Co., Ltd., ARTON manufactured by JSR Corporation, and the like), an acrylic resin, a polyester-based resin, and a polystyrene-based resin. A resin which does not easily contain water, such as a thermoplastic norbornene-based resin and a polystyrene-based resin, is preferable in order to suppress the total water content of the polarizing plate, and a thermoplastic norbornene-based resin is more preferable.

A thickness of the polarizer protective film is not particularly limited, but is preferably 40 μm or less and more preferably 25 μm or less from the viewpoint that the thickness of the polarizing plate can be reduced.

The laminate may have a pressure sensitive adhesive layer or an adhesive layer between respective layers in order to ensure adhesiveness between the respective layers.

Moreover, the laminate may have a transparent support between the respective layers.

The laminate may have another phase difference layer in addition to the phase difference layer formed of the composition containing the liquid crystal compound represented by General Formula (I).

The other phase difference layer may be an A-plate or a C-plate.

Furthermore, the total thickness of the phase difference layer, which is formed of the composition containing the reciprocal wavelength dispersible liquid crystal compound, and the other phase difference layer is preferably 100 μm or less, more preferably 40 μm or less, and still more preferably 20 μm or less, from the viewpoint of reduction in the thickness of the member. Moreover, from the viewpoint of manufacturing suitability, the total thickness is preferably 5 μm or greater, more preferably 10 μm or greater, and still more preferably 15 μm or greater.

<Method for Manufacturing Laminate>

A method for manufacturing the laminate is not particularly limited, and known methods are mentioned.

A method for manufacturing a laminate by first bonding a phase difference layer formed on a predetermined support to a polarizer, then peeling off the support to manufacture a polarizing plate including the phase difference layer and the polarizer, and interposing the polarizing plate between two substrates is mentioned.

Furthermore, in a case where the polarizing plate is manufactured, the phase difference layer may be formed directly on the polarizer.

In addition, in a case where the polarizing plate is manufactured, for example, it is preferable to include a step of continuously laminating the polarizer, and the positive A-plate and the positive C-plate, in a long state. The long polarizing plate is cut according to a size of a screen of the image display device to be used.

<Application>

The phase difference layer in the laminate according to the embodiment of the present invention is useful as an optical compensation film.

The optical compensation film is suitably used for optical compensation application of a liquid crystal display device (LCD), and can suppress a change in a tint in a case of being viewed from the oblique direction and light leakage during black display. For example, the optical compensation film can be provided between a polarizer and a liquid crystal cell of an IPS liquid crystal display device. In particular, in the optical compensation of the IPS liquid crystal, a remarkable effect is obtained by the laminate including the positive A-plate and the positive C-plate.

For example, in a case where the laminate according to the embodiment of the present invention includes the positive A-plate and the positive C-plate, the polarizer may be laminated on a surface on the positive A-plate side, or the polarizer may be laminated on a surface on the opposite side.

In a case where the polarizer, the positive A-plate, and the positive C-plate are arranged in this order, an angle formed by a slow axis direction of the positive A-plate and an absorption axis direction of the polarizing film is preferably in a range of 90°±10°.

Moreover, in a case where the polarizer, the positive C-plate, and the positive A-plate are arranged in this order, the slow axis direction of the positive A-plate and the absorption axis direction of the polarizing film are preferably parallel to each other.

As optical characteristics of the positive A-plate and the positive C-plate, it is preferable that the wavelength dispersion of Re or Rth exhibits reverse dispersibility, in particular, from the viewpoint that the change in a tint is suppressed.

In addition, the polarizing plate in the laminate according to the embodiment of the present invention is useful as an antireflection plate.

More specifically, in a case where the phase difference layer in the polarizing plate is a λ/4 plate, the laminate can be suitably applied as an antireflection plate. In particular, in a case where the laminate includes the positive A-plate and the positive C-plate, the total Rth of the positive A-plate and the positive C-plate can be adjusted to be close to zero, and visibility in an oblique direction is improved.

In a case where the laminate is used as an antireflection plate, the laminate can be applied to an image display device such as a liquid crystal display device (LCD), a plasma display panel (PDP), an electroluminescent display (ELD), and a cathode ray tube display device (CRT).

For example, the laminate according to the embodiment of the present invention can be provided as an antireflection plate on a light extraction surface side of an organic EL display device. In this case, external light is linearly polarized by the polarizer, and then passes through the phase difference plate to be circularly polarized. In a case where the light is reflected by a metal electrode of an organic EL display element or the like, the circularly polarized state is reversed, and in a case where the light passes through the phase difference plate again, the light is changed to linearly polarized light tilted by 90° compared to the time of incidence, reaches the polarizer, and is absorbed. As a result, the influence of the external light can be suppressed.

<Liquid Crystal Display Device and Organic Electroluminescent Device>

The laminate can be preferably used for an organic electroluminescent device (preferably, an organic electroluminescent (EL) display device), a liquid crystal display device, or the like.

(Liquid Crystal Display Device)

A liquid crystal display device according to the embodiment of the present invention is an example of the image display device, and includes the above-mentioned laminate according to the embodiment of the present invention and a liquid crystal cell.

In addition, in the present invention, it is preferable that the polarizer in the laminate according to the embodiment of the present invention is used as the polarizer on the front side among the polarizers provided on the both sides of the liquid crystal cell, and more preferable that the polarizer in the laminate according to the embodiment of the present invention is used as the polarizers on the front side and the rear side. Moreover, the phase difference layer included in the polarizing plate is preferably disposed on the liquid crystal cell side. In this case, the phase difference layer can be suitably used as an optical compensation film.

Furthermore, out of the two substrates in the laminate according to the embodiment of the present invention, the substrate disposed on the liquid crystal layer side may function as substrates disposed on both sides of the liquid crystal layer. For example, in a case where the substrate is a specific glass substrate, out of the two substrates in the laminate according to the embodiment of the present invention, the specific glass substrate disposed on the liquid crystal layer side may function as a glass substrate in a liquid crystal cell including a liquid crystal layer and two glass substrates interposing the liquid crystal layer.

More specifically, examples of the liquid crystal display device including the laminate include an aspect of an IPS liquid crystal display device for smartphone and tablet application, and as a configuration corresponding to the laminate, cover glass/(touch sensor)/(polarizer protective film)/polarizer/(polarizer protective film)/phase difference layer/glass for liquid crystal cell is assumed. In this case, the cover glass and the glass for a liquid crystal cell correspond to the above-mentioned substrate, and at least one of them is a specific glass substrate.

Moreover, members shown in parentheses in the above configuration indicate that the members are optional.

Hereinafter, the liquid crystal cell constituting the liquid crystal display device will be described in detail.

The liquid crystal cell used for the liquid crystal display device is preferably in a vertical alignment (VA) mode, an optical compensated bend (OCB) mode, an in-plane-switching (IPS) mode, or a twisted nematic (TN) mode, but is not limited thereto.

In a TN-mode liquid crystal cell, rod-shaped liquid crystalline molecules are substantially horizontally aligned in a case where a voltage is not applied, and further twist-aligned at 60° to 120°. The TN-mode liquid crystal cell is most often used in a color TFT liquid crystal display device and described in numerous documents.

In a VA-mode liquid crystal cell, rod-shaped liquid crystalline molecules are substantially vertically aligned in a case where a voltage is not applied. Examples of the VA-mode liquid crystal cell include (1) a VA-mode liquid crystal cell (described in JP1990-176625A (JP-H02-176625A)), in the narrow sense of the word, in which rod-shaped liquid crystalline molecules are substantially vertically aligned in a case where a voltage is not applied, but are substantially horizontally aligned in a case where a voltage is applied, (2) an (MVA-mode) liquid crystal cell (described in SID97, Digest of Tech. Papers (preprint) 28 (1997) 845) in which the VA mode is multi-domained for viewing angle enlargement, (3) a liquid crystal cell (described in preprint 58 to 59 of Japanese Liquid Crystal Society (1998)) in a mode (n-ASM mode) in which rod-shaped liquid crystalline molecules are substantially vertically aligned in a case where a voltage is not applied and are twisted and multi-domain-aligned in a case where a voltage is applied, and (4) a survival-mode liquid crystal cell (announced in LCD International 98). In addition, the liquid crystal cell may be of any of a patterned vertical alignment (PVA) type, a photo-alignment type (optical alignment), or a polymer-sustained alignment (PSA) mode. Details of these modes are specifically described in JP2006-215326A and JP2008-538819A.

In an IPS-mode liquid crystal cell, rod-shaped liquid crystalline molecules are aligned substantially parallel with respect to a substrate, and application of an electric field parallel to the substrate surface causes the liquid crystalline molecules to respond planarly. The IPS mode displays black in a state where an electric field is not applied and a pair of upper and lower polarizing plates have absorption axes which are orthogonal to each other. A method for improving the viewing angle by reducing light leakage during black display in an oblique direction using an optical compensation sheet (optical compensation film) is disclosed in JP1998-054982A (JP-H10-054982A), JP1999-202323A (JP-H11-202323A), JP1997-292522A (JP-H09-292522A), JP1999-133408A (JP-H11-133408A), JP1999-305217A (JP-H11-305217A), JP1998-307291A (JP-H10-307291A), and the like.

(Organic EL Display Device)

As an organic EL display device which is an example of the organic electroluminescent device according to the embodiment of the present invention, for example, an aspect in which the polarizing plate of the present invention and an organic EL display panel are provided in this order from a visual recognition side is suitably mentioned. The phase difference layer included in the polarizing plate is preferably disposed on the organic EL display panel side. In this case, the laminate according to the embodiment of the present invention is used as a so-called antireflection film.

Furthermore, out of the two substrates in the laminate according to the embodiment of the present invention, the substrate disposed on the organic EL display panel side may function as a sealing layer of the organic EL display panel. For example, in a case where the substrate is a specific glass substrate, out of the two specific glass substrates in the laminate according to the embodiment of the present invention, the specific glass substrate disposed on the organic EL display panel side may function as so-called sealing glass.

The organic EL display panel is a display panel constituted with an organic EL element in which an organic light emitting layer (organic electroluminescent layer) is sandwiched between electrodes (between a cathode and an anode). The configuration of the organic EL display panel is not particularly limited, and known configurations are adopted.

Among them, examples of the organic EL display device including the laminate include an aspect of an organic EL display device for smartphone and tablet application, and as a configuration corresponding to the laminate, cover glass/(touch sensor)/(polarizer protective film)/polarizer/(polarizer protective film)/phase difference layer/(touch sensor)/glass for organic EL sealing, high barrier film, or organic EL barrier film is assumed. In this case, the cover glass, the glass for organic EL sealing, the high barrier film, and the organic EL barrier film correspond to the above-mentioned substrate, and at least one of them is a specific glass substrate.

Moreover, members shown in parentheses in the above configuration indicate that the members are optional.

### EXAMPLES

Hereinafter, the present invention will be described in more detail with reference to Examples. However, the present invention is not limited thereto.

<Manufacture of Polarizer 1 with Protective Film>

A surface of a support of a cellulose triacetate film TJ25 (manufactured by FUJIFILM Corporation, thickness of 25 μm) was subjected to an alkali saponification treatment. Specifically, after the support was immersed in a 1.5 N sodium hydroxide aqueous solution at 55° C. for 2 minutes, the support was washed in a water-washing bath at room temperature and further neutralized with a 0.1 N sulfuric acid at 30° C. After neutralization, the support was washed in the water-washing bath at room temperature and further dried with hot air at 100° C. to obtain a polarizer protective film.

A roll-shaped polyvinyl alcohol film having a thickness of 75 μm was stretched in a machine direction (MD) in an iodine aqueous solution, and dried to obtain a polarizer 1 having a thickness of 14 μm.

The polarizer protective film was bonded to both surfaces of the polarizer 1 to manufacture a polarizer 1 with a protective film.

<Manufacture of Polarizer 2 with Protective Film>

A thickness and a stretching ratio of a polyvinyl alcohol film were adjusted in the same manner as in the polarizer 1 with a protective film, and the film was dried to obtain a polarizer 2 having a thickness of 9 μm.

The polarizer protective film was bonded to both surfaces of the polarizer 2 to manufacture a polarizer 2 with a protective film.

<Preparation of Glass Substrates 1 to 3>

Glass EAGLE-XG manufactured by Corning Incorporated was obtained as non-alkali glass, and used as a glass substrate 1 (Na₂O content: 0% by mass).

Glass PIREX (Na₂O content: 4% by mass) manufactured by Corning Incorporated was obtained as borosilicate glass, and used as a glass substrate 2.

As a glass substrate 3, a general soda-lime plate glass (Na₂O content: 17% by mass) was prepared.

The sizes of the glass substrates 1 to 3 were each a width of 70 mm×a length of 140 mm×a thickness of 1.1 mm.

In addition, here, in order to grasp the amount of Na₂O, which was presumed to promote the hydrolysis reaction of the liquid crystal compound, eluted from the glass substrate in the thermal durability test, a change in the mass of the glass in a case where an HCl solution (concentration: 5% by mass) preferentially eluting an alkaline component was brought into contact with the glass substrate a temperature of 95° C. for 24 hours was examined, and as a result, the reduction amount of the mass of the glass substrate 3 was four times that of the glass substrate 2. From this result, it was confirmed that in the glass substrate 3, Na₂O was more likely to be eluted.

### Example 1

The following compositions were put into a mixing tank and stirred to prepare a cellulose acetate solution used as a core layer cellulose acylate dope.

Core layer cellulose acylate dope

| | | |
|---|---|---|
| Cellulose acetate having acetyl substitution degree | 100 | parts by mass |
| of 2.88 | | |
| Polyester compound B described in Examples of | 12 | parts by mass |
| JP2015-227955A | | |
| The following compound G | 2 | parts by mass |
| Methylene chloride (first solvent) | 430 | parts by mass |
| Methanol (second solvent) | 64 | parts by mass |

Compound G

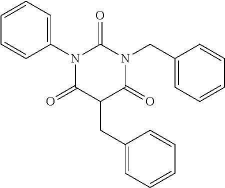 [SMILES: O=C1C(Cc2ccccc2)C(=O)N(c2ccccc2)C(=O)N1Cc1ccccc1]

10 parts by mass of the following matting agent solution was added to 90 parts by mass of the core layer cellulose acylate dope to prepare a cellulose acetate solution used as an outer layer cellulose acylate dope.

Matting agent solution

| | | |
|---|---|---|
| Silica particles with average particle | 2 | parts by mass |
| size of 20 nm (AEROSIL R972, manufactured | | |
| by NIPPON AEROSIL CO., LTD.) | | |
| Methylene chloride (first solvent) | 76 | parts by mass |
| Methanol (second solvent) | 11 | parts by mass |
| The above core layer cellulose acylate dope | 1 | part by mass |

The core layer cellulose acylate dope and the outer layer cellulose acylate dope were filtered through filter paper having an average pore diameter of 34 μm and a sintered metal filter having an average pore diameter of 10 μm, and then three layers composed of the core layer cellulose acylate dope and the outer layer cellulose acylate dopes on both sides thereof were simultaneously cast from a casting port onto a drum at 20° C. (band casting machine). The film was peeled off from the drum in a state of a solvent content ratio of approximately 20% by mass, the both ends of the film in the width direction were fixed with a tenter clip, and the film was dried while stretching the film at a stretching ratio of 1.1 times in the transverse direction. Thereafter, the obtained film was further dried by transporting the film between rolls in a heat treatment device to manufacture an optical film having a thickness of 40 μm, and the optical film was used as an optical film of Example 1. The core layer of the optical film of Example 1 had a thickness of 36 μm and the outer layers disposed on both sides of the core layer each had a thickness of 2 μm. Re(550) of the obtained optical film 1 was 0 nm.

Next, a coating liquid 1 for a photo-alignment film was prepared with reference to the description in JP2012-155308A of Example 3, and applied onto the optical film 1 with a wire bar. Thereafter, the obtained optical film was dried with hot air at 60° C. for 60 seconds to manufacture a coating film 1 having a thickness of 300 nm.

Subsequently, the following coating liquid A-1 for forming a positive A-plate was prepared.

Composition of coating liquid A-1 for forming positive A-plate

| | | |
|---|---|---|
| The following polymerizable liquid crystal compound X-1 | 20.00 | parts by mass |
| The following specific liquid crystal compound L-1 | 40.00 | parts by mass |
| The following specific liquid crystal compound L-2 | 40.00 | parts by mass |
| The following polymerization initiator S-1 | 0.60 | parts by mass |
| Leveling agent (the following compound T-1) | 0.10 | parts by mass |
| Methyl ethyl ketone (solvent) | 200.00 | parts by mass |
| Cyclopentanone (solvent) | 200.00 | parts by mass |

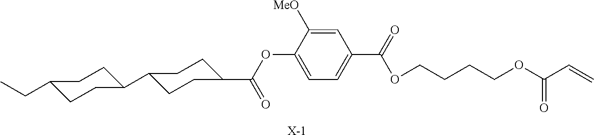

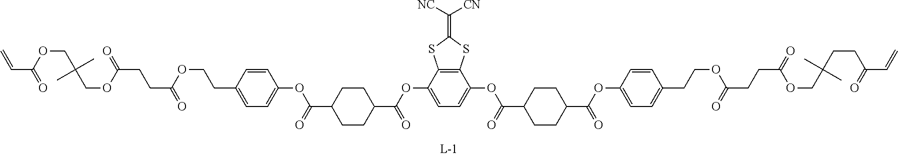 [SMILES: C=CC(=O)CCC(C)(C)COC(=O)CCC(=O)OCCc1ccc(OC(=O)C2CCC(C(=O)Oc3ccc(OC(=O)C4CCC(C(=O)Oc5ccc(CCOC(=O)CCC(=O)OCC(C)(C)COC(=O)C=C)cc5)CC4)c4c3SC(=C(C#N)C#N)S4)CC2)cc1]

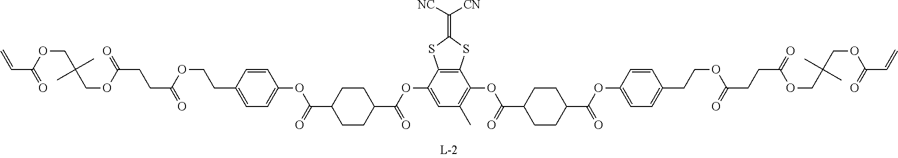 [SMILES: C=CC(=O)OCC(C)(C)COC(=O)CCC(=O)OCCc1ccc(OC(=O)C2CCC(C(=O)Oc3cc(C)c(OC(=O)C4CCC(C(=O)Oc5ccc(CCOC(=O)CCC(=O)OCC(C)(C)COC(=O)C=C)cc5)CC4)c4c3SC(=C(C#N)C#N)S4)CC2)cc1]

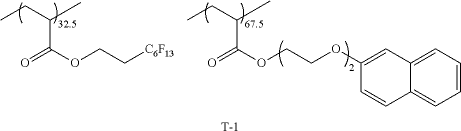

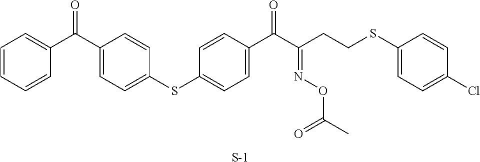

The manufactured coating film 1 was irradiated with ultraviolet rays in air using an ultra-high-pressure mercury lamp. In this case, a wire grid polarizer (ProFlux PPL02, manufactured by Moxtek, Inc.) was set so as to be parallel to a surface of the photo-alignment film 1, exposed, and subjected to a photo-alignment treatment to obtain a photo-alignment film 1.

At that time, the illuminance of the ultraviolet rays was 10 mJ/cm² in a UV-A range (A-wave of ultraviolet rays, integration of wavelengths of 320 to 380 nm).

Next, the coating liquid A-1 for forming a positive A-plate was applied onto the photo-alignment film 1 using a bar coater. The obtained coating film was heat-aged at a film surface temperature of 100° C. for 20 seconds and cooled to 90° C., and then a nematic alignment state was fixed by irradiation with 300 mJ/cm² of ultraviolet rays in air using an air-cooled metal halide lamp (manufactured by EYE GRAPHICS Co., Ltd.) to form a phase difference layer 1 (positive A-plate A-1), whereby an optical film with a phase difference layer 1 was manufactured.

A film thickness of the formed phase difference layer 1 was 2.5 μm. In the phase difference layer 1, Re(550) was 145 nm, Rth(550) was 73 nm, Re(550)/Re(450) was 1.12, Re(650)/Re(550) was 1.01, an inclination angle of an optical axis was 0°, and the specific liquid crystal compound was in homogeneous alignment.

A film with a pressure sensitive adhesive was manufactured with reference to the description in Example 1 of JP2017-134414A.

Next, a side of the phase difference layer 1 in the optical film with a phase difference layer 1 was bonded to one surface of the polarizer 1 with a protective film using the film with a pressure sensitive adhesive. At that time, an angle formed by an absorption axis of the polarizer and a slow axis of the phase difference layer 1 was 45°. Specifically, a pressure sensitive adhesive of the film with a pressure sensitive adhesive was bonded to one surface of the polarizer 1 with a protective film, a film in the film with a pressure sensitive adhesive was peeled off, and the phase difference layer 1 in the optical film with a phase difference layer 1 was further bonded to the pressure sensitive adhesive.

Subsequently, the optical film with a photo-alignment film 1 was removed from the obtained laminate by peeling at an interface between the photo-alignment film 1 and the phase difference layer 1 to manufacture a polarizing plate.

Thereafter, the obtained polarizing plate was cut so as to have the same width and length as those of the glass substrate 1, and the resultant was used as a polarizing plate 1. Next, the polarizing plate 1 was interposed between the glass substrates 1 from both sides using the film with a pressure sensitive adhesive to obtain a laminate 1 including the glass substrate 1, the polarizing plate, and the glass substrate 1 in this order.

### Example 2

A laminate 2 was obtained according to the same procedure as in Example 1, except that a coating liquid A-2 for forming a positive A-plate, which will be described later, was used instead of the coating liquid A-1 for forming a positive A-plate.

Furthermore, the coating liquid A-2 for forming a positive A-plate was prepared by using 100 parts by mass of the following specific liquid crystal compound L-6, instead of the polymerizable liquid crystal compound X-1, the specific liquid crystal compound L-1, and the specific liquid crystal compound L-2 of the coating liquid A-1 for forming a positive A-plate.

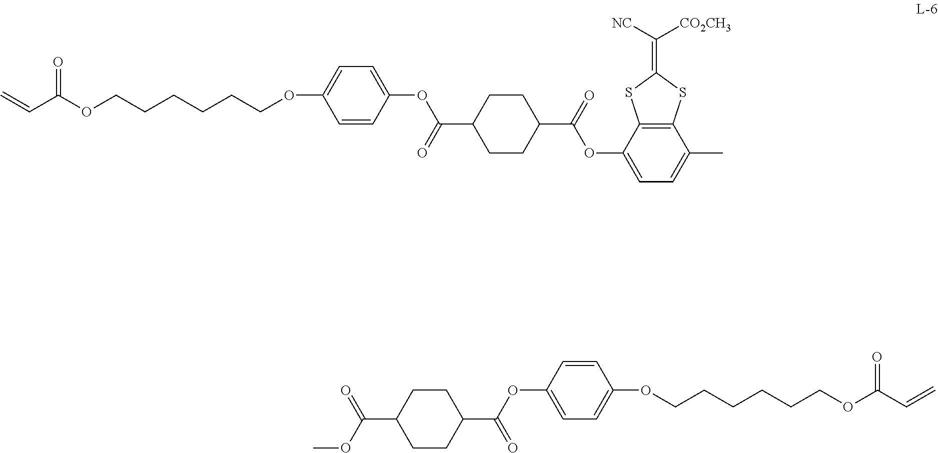

### Example 3

A laminate 3 was obtained according to the same procedure as in Example 1, except that a coating liquid A-3 for forming a positive A-plate, which will be described later, was used instead of the coating liquid A-1 for forming a positive A-plate. Furthermore, the coating liquid A-3 for forming a positive A-plate was prepared by using 100 parts by mass of the following specific liquid crystal compound L-9, instead of the polymerizable liquid crystal compound X-1, the specific liquid crystal compound L-1, and the specific liquid crystal compound L-2 of the coating liquid A-1 for forming a positive A-plate.

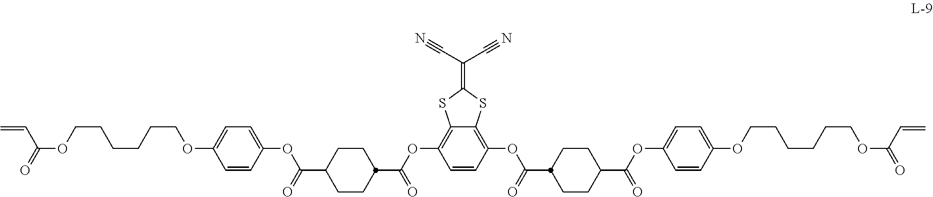

### Example 4

A laminate 4 was obtained according to the same procedure as in Example 1, except that a coating liquid A-6 for forming a positive A-plate, which will be described later, was used instead of the coating liquid A-1 for forming a positive A-plate.

The following coating liquid A-6 for forming a positive A-plate was prepared.

Composition of coating liquid A-6 for forming positive A-plate

| | | |
|---|---|---|
| The following specific liquid crystal compound L-7 | 100.00 | parts by mass |
| Polymerization initiator IRGACURE 369 (BASF Japan Ltd.) | 3.00 | parts by mass |
| Polymerization initiator OXE-03 (BASF Japan Ltd.) | 3.00 | parts by mass |
| ADEKA ARKLS NCI-831 (ADEKA CORPORATION) | 3.00 | parts by mass |
| Leveling agent BYK 361 N (BYK Japan KK) | 0.10 | parts by mass |
| Antioxidant BHT (Tokyo Chemical Industry Co., Ltd.) | 0.90 | parts by mass |
| Methyl ethyl ketone (solvent) | 60.00 | parts by mass |
| Cyclopentanone (solvent) | 200.00 | parts by mass |

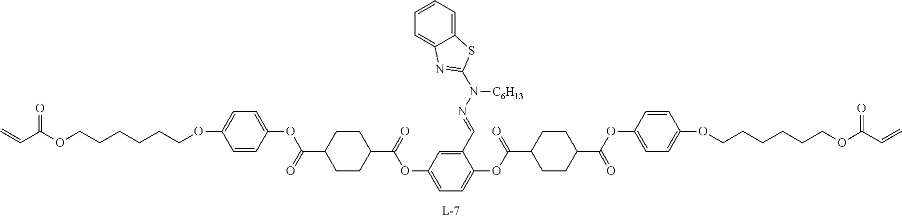

### Example 5

A laminate 5 was obtained according to the same procedure as in Example 1, except that a coating liquid A-7 for forming a positive A-plate, which will be described later, was used instead of the coating liquid A-1 for forming a positive A-plate.

Furthermore, the coating liquid A-7 for forming a positive A-plate was prepared by using the following specific liquid crystal compound L-8 instead of the specific liquid crystal compound L-7 of the coating liquid A-6 for forming a positive A-plate.

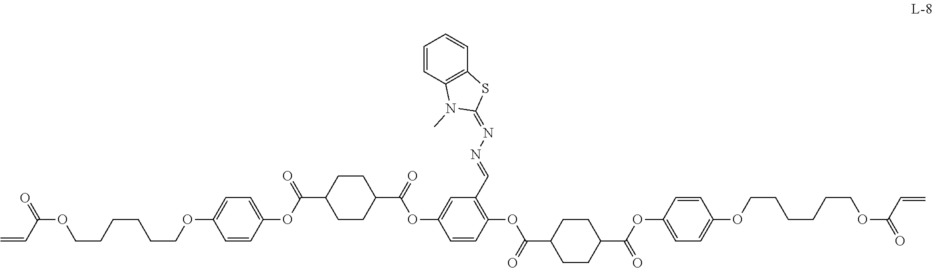 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c(/C=N/N=c4/sc5ccccc5n4C)c3)CC2)cc1]

### Example 6

A laminate 6 was obtained according to the same procedure as in Example 1, except that the laminate 6 including the glass substrate 1, the polarizing plate, and the glass substrate 2 in this order was obtained by using the glass substrate 1 and the glass substrate 2 instead of the two glass substrates 1.

Furthermore, the glass substrate 1 was disposed on the side closer to the positive A-plate in the polarizing plate, and the glass substrate 2 was disposed on the side far from the positive A-plate.

### Example 7

A laminate 7 was obtained according to the same procedure as in Example 6, except that the coating liquid A-2 for forming a positive A-plate, which will be described later, was used instead of the coating liquid A-1 for forming a positive A-plate.

### Example 8

A laminate 8 was obtained according to the same procedure as in Example 6, except that the coating liquid A-3 for forming a positive A-plate, which will be described later, was used instead of the coating liquid A-1 for forming a positive A-plate.

### Example 9

A laminate 9 was obtained according to the same procedure as in Example 6, except that the coating liquid A-6 for forming a positive A-plate, which will be described later, was used instead of the coating liquid A-1 for forming a positive A-plate.

### Example 10

A laminate 10 was obtained according to the same procedure as in Example 6, except that the coating liquid A-7 for forming a positive A-plate, which will be described later, was used instead of the coating liquid A-1 for forming a positive A-plate.

### Example 11

A laminate 11 was obtained according to the same procedure as in Example 6, except that a coating liquid A-4 for forming a positive A-plate, which will be described later, was used instead of the coating liquid A-1 for forming a positive A-plate.

Furthermore, the coating liquid A-4 for forming a positive A-plate was prepared by using the following specific liquid crystal compound L-5 instead of the specific liquid crystal compound L-7 of the coating liquid A-6 for forming a positive A-plate.

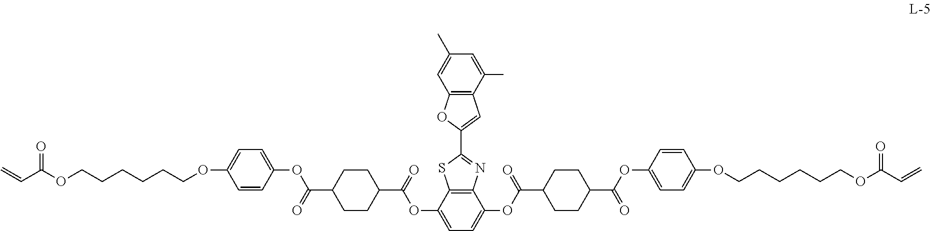 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c4sc(-c5cc6c(C)cc(C)cc6o5)nc34)CC2)cc1]

### Example 12

A laminate 12 was obtained according to the same procedure as in Example 6, except that a coating liquid A-5 for forming a positive A-plate, which will be described later, was used instead of the coating liquid A-1 for forming a positive A-plate.

Furthermore, the coating liquid A-5 for forming a positive A-plate was prepared by using the following specific liquid crystal compound L-10 instead of the specific liquid crystal compound L-7 of the coating liquid A-6 for forming a positive A-plate.

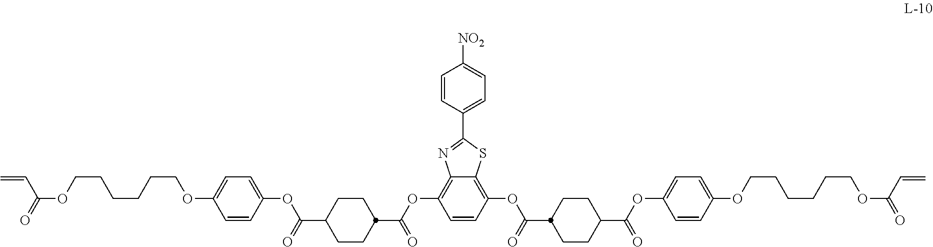

### Example 13

A laminate 13 was obtained according to the same procedure as in Example 6, except that a coating liquid A-8 for forming a positive A-plate, which will be described later, was used instead of the coating liquid A-1 for forming a positive A-plate.

Furthermore, the coating liquid A-8 for forming a positive A-plate was prepared by using the following specific liquid crystal compound L-11 instead of the specific liquid crystal compound L-7 of the coating liquid A-6 for forming a positive A-plate.

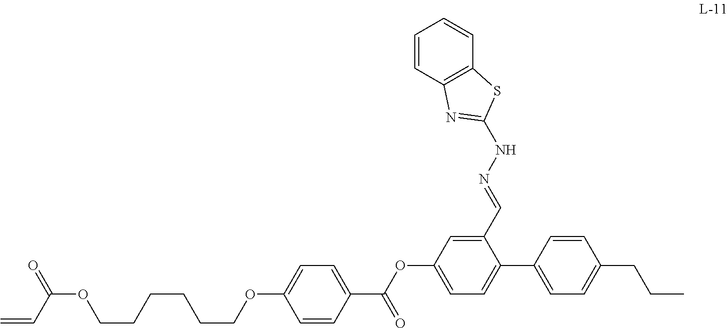 [SMILES: C=CC(=O)OCCCCCCOc1ccc(C(=O)Oc2ccc(-c3ccc(CCC)cc3)c(/C=N/Nc3nc4ccccc4s3)c2)cc1]

### Example 14

A laminate 14 was obtained according to the same procedure as in Example 6, except that a coating liquid A-9 for forming a positive A-plate, which will be described later, was used instead of the coating liquid A-1 for forming a positive A-plate.

Furthermore, the coating liquid A-9 for forming a positive A-plate was prepared by using the following specific liquid crystal compound L-12 instead of the specific liquid crystal compound L-7 of the coating liquid A-6 for forming a positive A-plate.

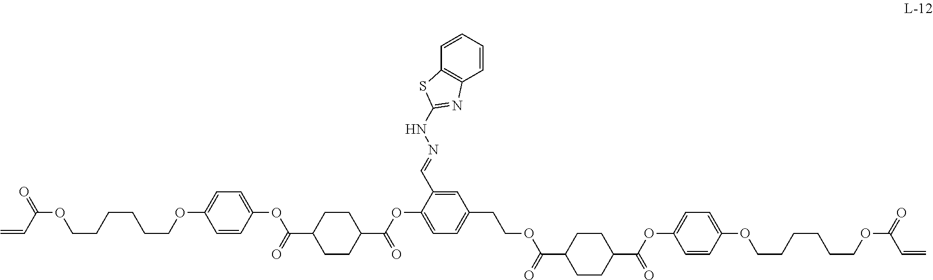 [SMILES: C=CC(=O)OCCCCCCOc1ccc(OC(=O)C2CCC(C(=O)OCCc3ccc(OC(=O)C4CCC(C(=O)Oc5ccc(OCCCCCCOC(=O)C=C)cc5)CC4)c(/C=N/Nc4nc5ccccc5s4)c3)CC2)cc1]

### Example 15

A laminate 15 was obtained according to the same procedure as in Example 6, except that the coating liquid A-10 for forming a positive A-plate, which will be described later, was used instead of the coating liquid A-1 for forming a positive A-plate.

Furthermore, a coating liquid A-10 for forming a positive A-plate was prepared by using the following specific liquid crystal compound L-13 instead of the specific liquid crystal compound L-7 of the coating liquid A-6 for forming a positive A-plate.

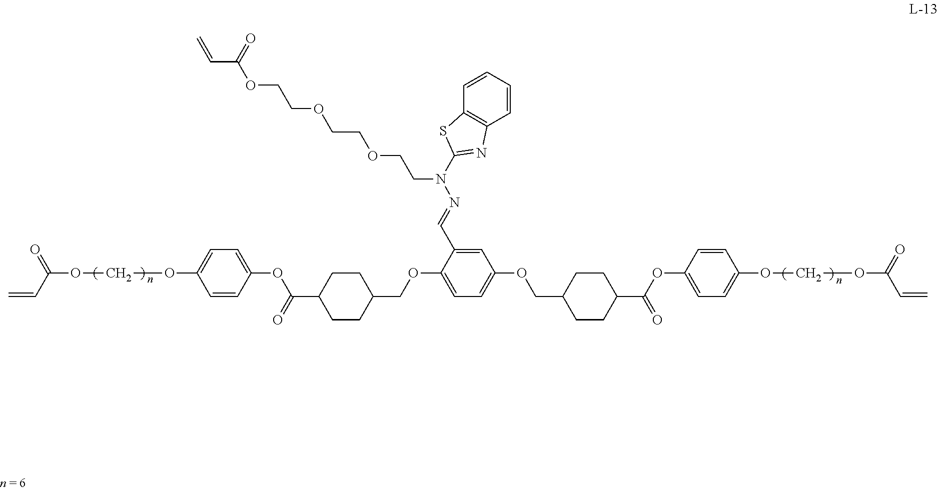

### Comparative Example 1

A laminate 16 was obtained according to the same procedure as in Example 1, except that the laminate 16 including the glass substrate 1, the polarizing plate, and the glass substrate 3 in this order was obtained by using the glass substrate 1 and the glass substrate 3 instead of the two glass substrates 1.

Furthermore, the glass substrate 1 was disposed on the side closer to the positive A-plate in the polarizing plate, and the glass substrate 3 was disposed on the side far from the positive A-plate.

### Comparative Example 2

A laminate 17 was obtained according to the same procedure as in Comparative Example 1, except that the coating liquid A-2 for forming a positive A-plate, which will be described later, was used instead of the coating liquid A-1 for forming a positive A-plate.

### Comparative Example 3

A laminate 18 was obtained according to the same procedure as in Comparative Example 1, except that the coating liquid A-3 for forming a positive A-plate, which will be described later, was used instead of the coating liquid A-1 for forming a positive A-plate.

### Comparative Example 4

A laminate 19 was obtained according to the same procedure as in Comparative Example 1, except that the coating liquid A-6 for forming a positive A-plate, which will be described later, was used instead of the coating liquid A-1 for forming a positive A-plate.

### Comparative Example 5

A laminate 20 was obtained according to the same procedure as in Comparative Example 1, except that the coating liquid A-7 for forming a positive A-plate, which will be described later, was used instead of the coating liquid A-1 for forming a positive A-plate.

### Example 16

Next, a side of the phase difference layer 1 in the optical film with a phase difference layer 1 was bonded to one surface of the polarizer 2 with a protective film using the film with a pressure sensitive adhesive. At that time, an angle formed by an absorption axis of the polarizer and a slow axis of the phase difference layer 1 was 45°. Specifically, a pressure sensitive adhesive of the film with a pressure sensitive adhesive was bonded to one surface of the polarizer 2 with a protective film, a film in the film with a pressure sensitive adhesive was peeled off, and the phase difference layer 1 in the optical film with a phase difference layer 1 was further bonded to the pressure sensitive adhesive.

Subsequently, the optical film with a photo-alignment film 1 was removed from the obtained laminate by peeling at an interface between the photo-alignment film 1 and the phase difference layer 1 to manufacture a polarizing plate.

Thereafter, the obtained polarizing plate was cut so as to have the same width and length as those of the glass substrate 1, and the resultant was used as a polarizing plate 21. Next, the polarizing plate 21 was interposed between the glass substrate 1 and the glass substrate 2 from both sides using the film with a pressure sensitive adhesive to obtain a laminate 21 including the glass substrate 1, the polarizing plate, and the glass substrate 2 in this order.

Furthermore, the glass substrate 1 was disposed on the side closer to the positive A-plate in the polarizing plate, and the glass substrate 2 was disposed on the side far from the positive A-plate.

<Thermal Durability Test>

Regarding the laminates 1 to 21, thermal durability of an in-plane retardation value (Re) of each central part of the laminates at a wavelength of 550 nm was evaluated using AxoScan (OPMF-1, manufactured by Axometrics, Inc.) according to the following indices. The results are shown in Table 1 below.

Furthermore, regarding the thermal durability test conditions, the test, in which the laminate was left in an environment of 85° C. for 336 hours, was performed. In a case where an evaluation result is “A” or higher, it can be determined that durability is favorable.

AA: The change amount between the initial Re value and the Re value after the test was less than 2% with respect to the initial value

A: The change amount between the initial Re value and the Re value after the test was 2% or greater and less than 7% with respect to the initial value

B: The change amount between the initial Re value and the Re value after the test was 7% or greater with respect to the initial value

The results of the above evaluation test are shown in Table 1.

TABLE 1

| | | Glass substrate | | | | | |
|---|---|---|---|---|---|---|---|
| | | (side far from positive A-plate) | | | Positive A-plate | | Thermal |
| | | | Na₂O | Polarizer | | Liquid crystal | durability |
| | Laminate | Type | [% by mass] | Type | Type | compound | test |
| Example 1 | 1 | Glass substrate 1 | 0 | Polarizer 1 | A-1 | X-1, L-1, and L-2 | AA |
| Example 2 | 2 | Glass substrate 1 | 0 | Polarizer 1 | A-2 | L-6 | AA |
| Example 3 | 3 | Glass substrate 1 | 0 | Polarizer 1 | A-3 | L-9 | AA |
| Example 4 | 4 | Glass substrate 1 | 0 | Polarizer 1 | A-6 | L-7 | AA |
| Example 5 | 5 | Glass substrate 1 | 0 | Polarizer 1 | A-7 | L-8 | AA |
| Example 6 | 6 | Glass substrate 2 | 4 | Polarizer 1 | A-1 | X-1, L-1, and L-2 | A |
| Example 7 | 7 | Glass substrate 2 | 4 | Polarizer 1 | A-2 | L-6 | A |
| Example 8 | 8 | Glass substrate 2 | 4 | Polarizer 1 | A-3 | L-9 | A |
| Example 9 | 9 | Glass substrate 2 | 4 | Polarizer 1 | A-6 | L-7 | A |
| Example 10 | 10 | Glass substrate 2 | 4 | Polarizer 1 | A-7 | L-8 | A |
| Example 11 | 11 | Glass substrate 2 | 4 | Polarizer 1 | A-4 | L-5 | AA |
| Example 12 | 12 | Glass substrate 2 | 4 | Polarizer 1 | A-5 | L-10 | AA |
| Example 13 | 13 | Glass substrate 2 | 4 | Polarizer 1 | A-8 | L-11 | AA |
| Example 14 | 14 | Glass substrate 2 | 4 | Polarizer 1 | A-9 | L-12 | AA |
| Example 15 | 15 | Glass substrate 2 | 4 | Polarizer 1 | A-10 | L-13 | AA |
| Comparative | 16 | Glass substrate 3 | 17 | Polarizer 1 | A-1 | X-1, L-1, and L-2 | B |
| Example 1 | | | | | | | |
| Comparative | 17 | Glass substrate 3 | 17 | Polarizer 1 | A-2 | L-6 | B |
| Example 2 | | | | | | | |
| Comparative | 18 | Glass substrate 3 | 17 | Polarizer 1 | A-3 | L-9 | B |
| Example 3 | | | | | | | |
| Comparative | 19 | Glass substrate 3 | 17 | Polarizer 1 | A-6 | L-7 | B |
| Example 4 | | | | | | | |
| Comparative | 20 | Glass substrate 3 | 17 | Polarizer 1 | A-7 | L-8 | B |
| Example 5 | | | | | | | |
| Example 16 | 21 | Glass substrate 2 | 4 | Polarizer 2 | A-1 | X-1, L-1, and L-2 | AA |

As shown in Table 1, it was confirmed that in a case of the laminate according to the embodiment of the present invention, a desired effect could be obtained.

In particular, from comparison of Example 1 and Example 6, it was confirmed that in a case where the Na₂O content was lower, a superior effect could be obtained.

Furthermore, from comparison of Examples 6 to 10 and Examples 11 to 15, it was confirmed that in a case where Ar³ in General Formula (III) is a divalent aromatic ring group represented by General Formula (II-1), or a case where an aspect in which Ar³ in General Formula (III) is a divalent aromatic ring group represented by General Formula (II-3) and at least one of D₁ or D₂ is a group other than —CO—O—, a superior effect could be obtained.

### Examples 17 to 32

(Manufacture of Positive C-Plate 1)

As a temporary support, a triacetyl cellulose film “Z-TAC” (manufactured by FUJIFILM Corporation) was used (the film will be referred to as a cellulose acylate film 2).

The cellulose acylate film 2 was allowed to pass through a dielectric heating roll at a temperature of 60° C., the film surface temperature was elevated to 40° C., then an alkaline solution having the composition shown below was applied onto one surface of the film at an application amount of 14 ml/m² using a bar coater, and the film was transported for 10 seconds under a steam-type far infrared heater manufactured by NORITAKE CO., LIMITED while heating at 110° C.

Next, pure water was applied onto the film at 3 ml/m² using the same bar coater.

Subsequently, water-washing using a fountain coater and drainage using an air knife were repeated three times, and then the film was transported to a drying zone at 70° C. for 10 seconds for drying to manufacture a cellulose acylate film 2 subjected to the alkali saponification treatment.

Composition of alkaline solution (parts by mass)

| | | |
|---|---|---|
| Potassium hydroxide | 4.7 | parts by mass |
| Water | 15.8 | parts by mass |
| Isopropanol | 63.7 | parts by mass |
| Surfactant SF-1 | 1.0 | part by mass |
| (C₁₄H₂₉O(CH₂CH₂O)₂₀H) | | |
| Propylene glycol | 14.8 | parts by mass |

A coating liquid 2 for forming an alignment film having the following composition was continuously applied onto the cellulose acylate film 2 subjected to the alkali saponification treatment using a wire bar of #8. The obtained film was dried with hot air at 60° C. for 60 seconds and further dried with hot air at 100° C. for 120 seconds to form an alignment film.

Composition of coating liquid 2 for forming alignment film

| | | |
|---|---|---|
| Polyvinyl alcohol | 2.4 | parts by mass |
| (manufactured by KURARAY CO., | | |
| LTD., PVA 103) | | |
| Isopropyl alcohol | 1.6 | parts by mass |
| Methanol | 36 | parts by mass |
| Water | 60 | parts by mass |

A coating liquid C-1 for forming a positive C-plate, which will be described later, was applied onto the alignment film, the obtained coating film was aged at 60° C. for 60 seconds and then irradiated with 1,000 mJ/cm² of ultraviolet rays in air using an air-cooled metal halide lamp (manufactured by EYE GRAPHICS Co., Ltd.) at 70 mW/cm², and the alignment state was fixed to vertically align a liquid crystal compound, thereby manufacturing a positive C-plate 1. Rth(550) of the obtained positive C-plate 1 was −60 nm.

Composition of coating liquid C-1 for forming positive C-plate

| | | |
|---|---|---|
| The following liquid crystal compound L-11 | 80 | parts by mass |
| The following liquid crystal compound L-12 | 20 | parts by mass |
| The following vertical alignment agent (S01) for liquid crystal compound | 1 | part by mass |
| Ethylene oxide-modified trimethylol propane triacrylate | 8 | parts by mass |
| (V#360, manufactured by OSAKA ORGANIC CHEMICAL INDUSTRY LTD.) | | |
| IRGACURE 907 (manufactured by BASF SE) | 3 | parts by mass |
| KAYACURE DETX (manufactured by Nippon Kayaku Co., Ltd.) | 1 | part by mass |
| The following compound B03 | 0.4 | parts by mass |
| Methyl ethyl ketone | 170 | parts by mass |
| Cyclohexanone | 30 | parts by mass |

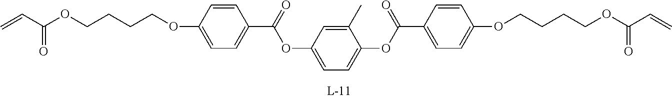 [SMILES: C=CC(=O)OCCCCOc1ccc(C(=O)Oc2ccc(OC(=O)c3ccc(OCCCCOC(=O)C=C)cc3)c(C)c2)cc1]

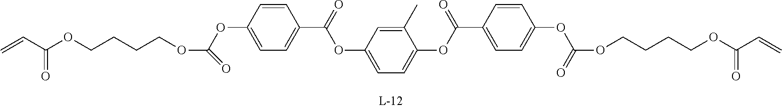 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]

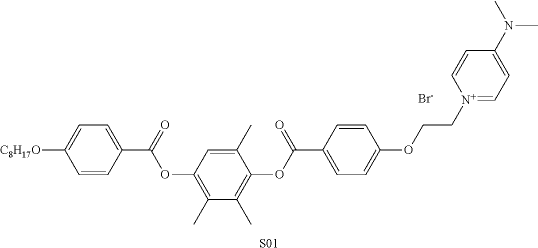

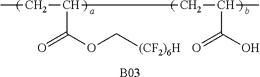

(Manufacture of Polarizing Plate)

The positive C-plate 1 manufactured above was bonded onto each positive A-plate side of the polarizing plates of Examples 1 to 16 using the film with a pressure sensitive adhesive, and the alignment film and the cellulose acylate film 2 were removed to obtain polarizing plates 22 to 37.

(Manufacture of Organic EL Display Device)

GALAXY S5 manufactured by SAMSUNG, which has an organic EL display panel (organic EL display element) installed therein, was disassembled, a touch panel with a circularly polarizing plate was peeled from the organic EL display device, the circularly polarizing plate was further peeled from the touch panel, and the organic EL display element (with sealing glass), the touch panel, and the circularly polarizing plate were each isolated. Subsequently, the isolated touch panel was bonded again to the organic EL display element, the manufactured polarizing plate was bonded onto the touch panel so that the side of the positive C-plate was the panel side, and cover glass was further bonded thereto to manufacture an organic EL display device. Furthermore, the glass substrate 1 was used as the cover glass and the sealing glass.

In the obtained organic EL display device, a laminate including the sealing glass (corresponding to a glass plate), the polarizing plate (any of the polarizing plates 22 to 37), and the cover glass (corresponding to a glass plate) was included.

### EXPLANATION OF REFERENCES

10, 20, 30, 40: Laminate
11: Polarizer protective film
12: Polyvinyl alcohol polarizer
13: Polarizer protective film
14: Positive A-plate
15: Positive C-plate
16: Photo-alignment film
17A: Glass substrate
17B: Glass substrate

What is claimed is:

1. A laminate comprising:
two substrates; and
a polarizing plate disposed between the two substrates,
wherein the polarizing plate has a polarizer and a phase difference layer,
the phase difference layer is a layer formed of a composition containing a reciprocal wavelength dispersible liquid crystal compound,
one of the two substrates is a glass substrate having a Na₂O content of 5% by mass or less, and
the other of the two substrates is a glass substrate having a Na₂O content of 5% by mass or less, an inorganic compound film having a moisture permeability of 10⁻³ g/m²·day or less and a thickness of less than 1 μm, or an organic-inorganic hybrid film having a moisture permeability of 10⁻³ g/m²·day or less.

2. The laminate according to claim 1,
wherein the polarizer contains a polyvinyl alcohol-based resin.

3. The laminate according to claim 1,
wherein the reciprocal wavelength dispersible liquid crystal compound is a liquid crystal compound represented by General Formula (II),
L₁-G₁-D₁-Ar-D₂-G₂-L₂ (II)
in General Formula (II), D₁ and D₂ each independently represent a single bond, —O—, —CO—O—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—,
where R¹, R², R³, and R⁴ each independently represent a hydrogen atom, a fluorine atom, or an alkyl group having 1 to 4 carbon atoms;
G₁ and G₂ each independently represent a divalent alicyclic hydrocarbon group having 5 to 8 carbon atoms, or a divalent aromatic hydrocarbon group having 5 to 8 carbon atoms, and a methylene group contained in the alicyclic hydrocarbon group may be substituted with —O—, —S—, or —NH—;
L₁ and L₂ each independently represent a monovalent organic group, and at least one selected from the group consisting of L₁ and L₂ represents a monovalent group having a polymerizable group; and
Ar represents a divalent aromatic ring group represented by General Formula (II-1), General Formula (II-2), General Formula (II-3), or General Formula (II-4), 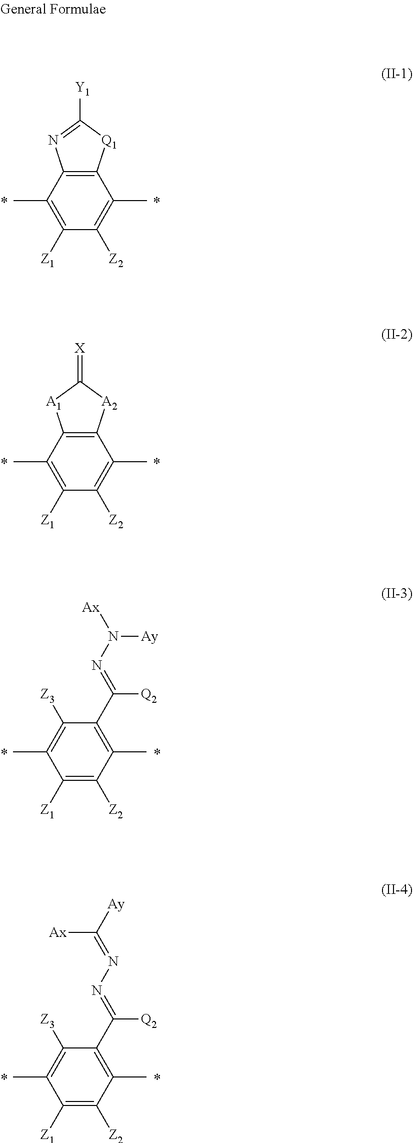
in General Formulae (II-1) to (II-4), Q₁ represents —S—, —O—, or —NR¹¹—, R¹¹ represents a hydrogen atom or an alkyl group having 1 to 6 carbon atoms, Y₁ represents an aromatic hydrocarbon group having 6 to 12 carbon atoms or an aromatic heterocyclic group having 3 to 12 carbon atoms, Z₁, Z₂, and Z₃ each independently represent a hydrogen atom, an aliphatic hydrocarbon group having 1 to 20 carbon atoms, an alicyclic hydrocarbon group having 3 to 20 carbon atoms, a monovalent aromatic hydrocarbon group having 6 to 20 carbon atoms, a halogen atom, a cyano group, a nitro group, —NR¹²R¹³, or —SR¹², Z₁ and Z₂ may be bonded to each other to form an aromatic ring or an aromatic heterocyclic ring, R¹² and R¹³ each independently represent a hydrogen atom or an alkyl group having 1 to 6 carbon atoms, A₁ and A₂ are each independently a group selected from the group consisting of —O—, —NR²¹—, —S—, and —CO—, where R²¹ represents a hydrogen atom or a substituent, X represents a hydrogen atom, or a non-metallic atom of Group 14 to Group 16, to which a substituent may be bonded, Ax represents an organic group which has 2 to 30 carbon atoms and has at least one aromatic ring selected from the group consisting of an aromatic hydrocarbon ring and an aromatic heterocyclic ring, Ay represents a hydrogen atom, an alkyl group which has 1 to 6 carbon atoms and may have a substituent, or an organic group which has 2 to 30 carbon atoms and has at least one aromatic ring selected from the group consisting of an aromatic hydrocarbon ring and an aromatic heterocyclic ring, the aromatic rings in Ax and Ay may each have a substituent, Ax and Ay may be bonded to each other to form a ring, and Q₂ represents a hydrogen atom or an alkyl group which has 1 to 6 carbon atoms and may have a substituent; and * represents a bonding position.

4. The laminate according to claim 1,
wherein a thickness of the polarizer is less than 10 μm.

5. The laminate according to claim 1,
wherein Re(450) which is an in-plane retardation value of the phase difference layer at a wavelength of 450 nm, Re(550) which is an in-plane retardation value of the phase difference layer at a wavelength of 550 nm, and Re(650) which is an in-plane retardation value of the phase difference layer at a wavelength of 650 nm satisfy a relationship of Re(450)≤Re(550)≤Re(650).

6. The laminate according to claim 1,
wherein the phase difference layer is a positive A-plate.

7. The laminate according to claim 1,
wherein the phase difference layer is a λ/4 plate.

8. The laminate according to claim 1, further comprising:
a polarizer protective film on at least one surface of the polarizer,
wherein at least one polarizer protective film contains a thermoplastic norbornene-based resin.

9. A liquid crystal display device comprising:
the laminate according to claim 1.

10. An organic electroluminescent device comprising:
the laminate according to claim 1.

11. The laminate according to claim 2,
wherein the reciprocal wavelength dispersible liquid crystal compound is a liquid crystal compound represented by General Formula (II),
L₁-G₁-D₁-Ar-D₂-G₂-L₂ (II)
in General Formula (II), D₁ and D₂ each independently represent a single bond, —O—, —CO—O—, —C(═S)O—, —CR¹R²—, —CR¹R²—CR³R⁴—, —O—CR¹R²—, —CR¹R²—O—CR³R⁴—, —CO—O—CR¹R²—, —O—CO—CR¹R²—, —CR¹R²—CR³R⁴—O—CO—, —CR¹R²—O—CO—CR³R⁴—, —CR¹R²—CO—O—CR³R⁴—, —NR¹—CR²R³—, or —CO—NR¹—,
where R¹, R², R³, and R⁴ each independently represent a hydrogen atom, a fluorine atom, or an alkyl group having 1 to 4 carbon atoms;
G₁ and G₂ each independently represent a divalent alicyclic hydrocarbon group having 5 to 8 carbon atoms, or a divalent aromatic hydrocarbon group having 5 to 8 carbon atoms, and a methylene group contained in the alicyclic hydrocarbon group may be substituted with —O—, —S—, or —NH—;
L₁ and L₂ each independently represent a monovalent organic group, and at least one selected from the group consisting of L₁ and L₂ represents a monovalent group having a polymerizable group; and
Ar represents a divalent aromatic ring group represented by General Formula (II-1), General Formula (II-2), General Formula (II-3), or General Formula (II-4), 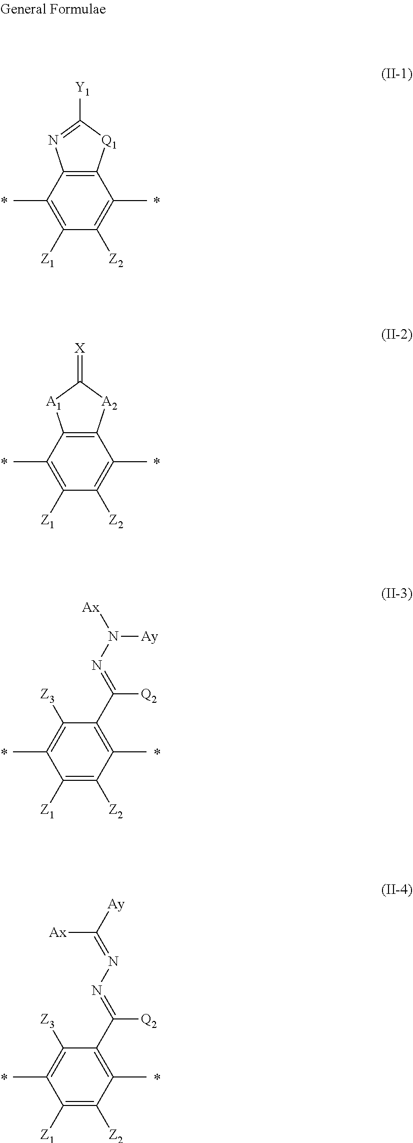
in General Formulae (II-1) to (II-4), Q₁ represents —S—, —O—, or —NR¹¹—, R¹¹ represents a hydrogen atom or an alkyl group having 1 to 6 carbon atoms, Y₁ represents an aromatic hydrocarbon group having 6 to 12 carbon atoms or an aromatic heterocyclic group having 3 to 12 carbon atoms, Z₁, Z₂, and Z₃ each independently represent a hydrogen atom, an aliphatic hydrocarbon group having 1 to 20 carbon atoms, an alicyclic hydrocarbon group having 3 to 20 carbon atoms, a monovalent aromatic hydrocarbon group having 6 to 20 carbon atoms, a halogen atom, a cyano group, a nitro group, —NR¹²R¹³, or —SR¹², Z₁ and Z₂ may be bonded to each other to form an aromatic ring or an aromatic heterocyclic ring, R¹² and R¹³ each independently represent a hydrogen atom or an alkyl group having 1 to 6 carbon atoms, A₁ and A₂ are each independently a group selected from the group consisting of —O—, —NR²¹—, —S—, and —CO—, where R²¹ represents a hydrogen atom or a substituent, X represents a hydrogen atom, or a non-metallic atom of Group 14 to Group 16, to which a substituent may be bonded, Ax represents an organic group which has 2 to 30 carbon atoms and has at least one aromatic ring selected from the group consisting of an aromatic hydrocarbon ring and an aromatic heterocyclic ring, Ay represents a hydrogen atom, an alkyl group which has 1 to 6 carbon atoms and may have a substituent, or an organic group which has 2 to 30 carbon atoms and has at least one aromatic ring selected from the group consisting of an aromatic hydrocarbon ring and an aromatic heterocyclic ring, the aromatic rings in Ax and Ay may each have a substituent, Ax and Ay may be bonded to each other to form a ring, and Q₂ represents a hydrogen atom or an alkyl group which has 1 to 6 carbon atoms and may have a substituent; and * represents a bonding position.

12. The laminate according to claim 2,
wherein a thickness of the polarizer is less than 10 μm.

13. The laminate according to claim 2,
wherein Re(450) which is an in-plane retardation value of the phase difference layer at a wavelength of 450 nm, Re(550) which is an in-plane retardation value of the phase difference layer at a wavelength of 550 nm, and Re(650) which is an in-plane retardation value of the phase difference layer at a wavelength of 650 nm satisfy a relationship of Re(450)≤Re(550)≤Re(650).

14. The laminate according to claim 2,
wherein the phase difference layer is a positive A-plate.

15. The laminate according to claim 2,
wherein the phase difference layer is a λ/4 plate.

16. The laminate according to claim 2, further comprising:
a polarizer protective film on at least one surface of the polarizer,
wherein at least one polarizer protective film contains a thermoplastic norbornene-based resin.

17. A liquid crystal display device comprising:
the laminate according to claim 2.

18. An organic electroluminescent device comprising:
the laminate according to claim 2.

19. The laminate according to claim 3,
wherein a thickness of the polarizer is less than 10 μm.

20. The laminate according to claim 3,
wherein Re(450) which is an in-plane retardation value of the phase difference layer at a wavelength of 450 nm, Re(550) which is an in-plane retardation value of the phase difference layer at a wavelength of 550 nm, and Re(650) which is an in-plane retardation value of the phase difference layer at a wavelength of 650 nm satisfy a relationship of Re(450)≤Re(550)≤Re(650).
